(19) United States
(12) Patent Application Publication
(10) Pub. No.: US 2026/0244113 A1
(43) Pub. Date: Aug. 20, 2026

(54) Controlled Environment Photoresist Processing System and Method

(71) Applicant: IMEC VZW, Leuven (BE)

(72) Inventors: Ivan Pollentier, Langdrop (BE); Fabian Holzmeier, Loonbeek (BE); Kevin Dorney, Herent (BE); Hyo Seon Suh, Herent (BE); Sonia Castellanos Ortega, Leuven (BE)

(21) Appl. No.: 19/636,502

(22) Filed: Apr. 1, 2026

Related U.S. Application Data
(63) Continuation-in-part of application No. PCT/EP2025/078176, filed on Oct. 1, 2025.
(60) Provisional application No. 63/701,653, filed on Oct. 1, 2024.
(60) Provisional application No. 63/885,723, filed on Sep. 22, 2025.

(51) Int. Cl. G03F 7/00

(52) U.S. Cl. CPC G03F 7/70591; G03F 7/70525; G03F 7/7085; G03F 7/70875

(57) ABSTRACT

A tool for evaluating photoresist chemical changes during lithographic processes comprising: a radiation exposure station for exposing photoresist samples to radiation; a thermal processing station for thermally processing photoresist samples; an intermediate analysis station separate from the exposure station and the thermal processing station, the intermediate analysis station comprising a system configured for analyzing photoresist samples, and environmental isolation means between the stations enabling independent environments in each station during operation; an atmosphere control system configured to establish different atmospheric conditions in each station, and a sample transfer system for transferring photoresist samples between the stations while maintaining environmental isolation.

### CROSS-REFERENCE TO RELATED APPLICATIONS

The present application is a non-provisional patent application claiming priority to PCT EP 25078176 filed on Oct. 1, 2025, which claims priority to U.S. Provisional Application No. 63/701,653 filed on Oct. 1, 2024, and U.S. Provisional Application No. 63/885,723 filed on Sep. 22, 2025, the contents of each of which are hereby incorporated by reference.

### FIELD OF THE DISCLOSURE

The present embodiments relate to the field of semiconductor lithography metrology, and more specifically to equipment for studying photoresist chemistry during lithographic processing.

### BACKGROUND

Photolithography is a cornerstone technology in the semiconductor manufacturing industry, enabling the creation of ever-smaller and more complex integrated circuits. At the heart of this process are photoresists, specialized materials designed to undergo chemical transformations when exposed to specific wavelengths of light. These transformations ultimately allow for the transfer of intricate patterns onto semiconductor substrates.

The lithographic process involves several distinct steps. Typically, photoresist is applied to a wafer through wet deposition methods using solvents or through dry techniques such as chemical vapor deposition (CVD). The coated wafer is then exposed to light of specific wavelengths, including KrF, ArF, or extreme ultraviolet (EUV) radiation. Following exposure, the wafer undergoes one or more baking steps, known as post-exposure bakes (PEB), and finally a development step that may be wet or dry in nature. Throughout this sequence, the photoresist undergoes complex molecular transformations that ultimately determine the quality and precision of the resulting patterns.

In semiconductor manufacturing facilities, wafers may be exposed to cleanroom atmosphere during transfers between process steps.

Understanding the precise nature of chemical changes in photoresists is challenging in production environments. When evaluating lithographic outcomes, manufacturers typically assess the final results after the complete process has been executed. The quality of lithographic patterns is generally evaluated through metrics such as critical dimension (CD) process window, CD uniformity, feature roughness, and the presence of stochastic failures. However, these measurements do not directly reveal the underlying molecular changes that occurred during each processing step.

The photoresist's molecular composition can be significantly influenced by the surrounding atmospheric environment. This is particularly evident during the times between process steps when the wafer may be exposed to varying conditions. For instance, some photoresists, including metal oxide resists (MOR) used in EUV lithography, have shown sensitivity to environmental factors such as humidity levels and airborne contaminants. These environmental variables can introduce inconsistencies in the lithographic process.

This sensitivity is particularly evident during delay times between processing steps. For instance, there is a direct correlation between the duration of the post-coating delay (PCD) and the deviation from the target critical dimension (CD). This deviation has been linked to environmental factors such as ambient humidity, which can alter the photoresist film's properties before it even reaches the exposure step.

Similarly, the post-exposure delay (PED), the time between exposure and post-exposure bake (PEB), is another critical window for environmental influence. As shown in FIG. 8, both humidity and the concentration of airborne molecular contaminants (AMCs) during PED can significantly alter the dose-dependent chemical reactions, such as fractional ligand cleavage. FIG. 9 schematically illustrates how these ambient molecules, like water (H₂O) and AMCs, can infiltrate the resist structure during the PED and PEB stages, leading to unintended chemical changes and degrading the performance and stability of these sensitive materials.

The chemical transformations within photoresists are multifaceted. While a primary chemical reaction may dominate, numerous secondary reactions can occur simultaneously. These parallel processes can impact the final lithographic result, yet distinguishing between them and quantifying their relative contributions presents significant difficulties.

Challenges remain in developing comprehensive approaches for investigating photoresist behavior.

### SUMMARY

It is an object of embodiments of the present disclosure to enable precise characterization of molecular changes occurring in photoresists during lithographic processes. This objective is accomplished by the aspects of the present disclosure.

In a first aspect, the present disclosure relates to a tool for evaluating photoresist chemical changes during lithographic processes, comprising a radiation exposure station for exposing photoresist samples to radiation; a thermal processing station for thermally processing photoresist samples; an intermediate analysis station separate from the exposure station and the thermal processing station, the intermediate analysis station comprising a system configured for analyzing photoresist samples, and environmental isolation means between the stations enabling independent environments in each station during operation; an atmosphere control system configured to establish different atmospheric conditions in each station, and a sample transfer system for transferring photoresist samples between the stations while maintaining environmental isolation.

In a second aspect, the present disclosure relates to a method for evaluating photoresist chemical changes during lithographic processes in a tool according to the first aspect, comprising exposing a photoresist sample to radiation in the radiation exposure station under a first controlled atmosphere; transferring the exposed photoresist sample to the intermediate analysis station while maintaining environmental isolation; performing analysis of the photoresist sample in the intermediate analysis station under a second controlled atmosphere; transferring the analyzed sample to the thermal processing station while maintaining environmental isolation; thermally processing the photoresist sample in the thermal processing station under a third controlled atmosphere; and transferring the thermally processed sample back to the intermediate analysis station while maintaining environmental isolation, and performing further analysis of the photoresist sample in the intermediate analysis station under a fourth controlled atmosphere, wherein the first, second, third, and fourth controlled atmospheres are independently controlled.

In a third aspect, the present disclosure relates to a system comprising the tool according to the first aspect, and a controller for carrying out at least some steps of the method according to the second aspect.

In a fourth aspect, the present disclosure relates to a computer program comprising instructions which, when executed by the controller of the system of the third aspect, cause the controller to carry out the method according to the second aspect.

In a fifth aspect, the present disclosure relates to a computer-readable medium having stored thereon the computer program of the fourth aspect.

In a sixth aspect, the present disclosure relates to a method for optimizing lithographic process conditions for a photoresist material, comprising evaluating photoresist chemical changes using the method of the second aspect under multiple sets of process conditions; correlating the photoresist chemical changes with lithographic performance metrics; and identifying optimal process conditions based on the correlations.

In a seventh aspect, the present disclosure relates to a system for thermally processing MOR samples in an oxygen environment. The system includes a thermal processing chamber. The system further includes a hot plate disposed within the thermal processing chamber. The hot plate is configured to support a metal oxide resist (MOR) photoresist sample. Further, the system includes an O₂ gas source coupled to the thermal processing chamber by way of a first mass flow controller, and a controller having at least one processor and a memory storing program instructions. The at least one processor executes the program instructions so as to carry out operations. The operations include causing the hot plate to heat the MOR photoresist sample at a predetermined temperature for a predetermined period of time. The predetermined temperature is within a range of 50° C.-350° C., and the predetermined period of time is within a range of 60 seconds to 240 seconds. The operations further include adjusting the first mass flow controller to maintain a predetermined atmospheric condition in the thermal processing chamber. The predetermined atmospheric condition includes an O₂ concentration within a range of 0% to 50%, for example in the range of 22% to 50%.

In an eighth aspect, the present disclosure relates to a method for thermally processing MOR samples in an oxygen environment. The method includes adjusting a first mass flow controller to control a flow of O₂ into a thermal processing chamber so as to maintain a predetermined atmospheric condition in the thermal processing chamber. The predetermined atmospheric condition includes an O₂ concentration of 0% to 50%, for example in the range of 22% to 50%. The method further includes introducing a metal oxide resist (MOR) photoresist sample into the thermal processing chamber. Even further, the method includes thermally processing, by a hot plate in the thermal processing chamber, the MOR photoresist sample at a predetermined temperature for a predetermined period of time, while maintaining the predetermined atmospheric condition within the thermal processing chamber. The predetermined temperature is within a range of 50° C.-350° C., and the predetermined period of time is within a range of 60 seconds to 240 seconds.

In example embodiments of the present disclosure, step-specific investigation of photoresist chemistry may be performed without interruption by uncontrolled ambient exposure.

Further in example embodiments of the present disclosure, a single platform may allow samples to remain in continuously isolated environments while moving between processing stations.

Additionally in example embodiments of the present disclosure, independent atmospheric conditions may be established for each process step, thereby enabling systematic exploration of environmental variables.

Even further, in example embodiments of the present disclosure, in-situ spectroscopic and analytical measurements may be carried out at multiple stages of the lithographic workflow.

Further, in example embodiments of the present disclosure, molecular-level data acquired during processing may be directly correlated with downstream lithographic performance metrics.

Additionally, in example embodiments of the present disclosure, the need for off-line metrology may be reduced, shortening experimental cycles and limiting sample handling errors.

Further, in example embodiments of the present disclosure, reproducibility of chemical characterization may be enhanced through temperature-stable measurement conditions.

Even further, in example embodiments of the present disclosure, users may rapidly screen process parameters such as gas composition, humidity and delay time within a single controlled sequence.

Additionally, in example embodiments of the present disclosure, diverse resist chemistries, including next-generation EUV materials, may be studied under identical, well-defined conditions.

Further, in example embodiments of the present disclosure, transfer mechanisms designed for minimal contamination may support high-fidelity analysis of trace chemical events.

Even further, in example embodiments of the present disclosure, modular architecture may permit future integration of additional processing or measurement units without redesigning the entire system.

Additionally, in example embodiments of the present disclosure, quantitative insight obtained from the platform may guide optimization of industrial lithography processes.

Further, in example embodiments of the present disclosure, experimenters may gain flexibility to apply either vacuum, inert, oxidative or humid ambients on demand during thermal or radiative treatments.

Additionally, in example embodiments of the present disclosure, multiple samples or multiple exposure conditions may be evaluated in a single run, improving research throughput.

Even further, in example embodiments of the present disclosure, consistent environmental control may reduce variability, thereby increasing confidence in comparative studies across different laboratories or timeframes.

Particular aspects of the disclosure are set out in the accompanying independent and dependent claims. Features from the dependent claims may be combined with features of the independent claims and with features of other dependent claims as appropriate and not merely as explicitly set out in the claims.

The above and other characteristics, features and advantages of the present disclosure will become apparent from the following detailed description, taken in conjunction with the accompanying drawings, which illustrate, by way of example, the principles of the disclosure. This description is given for the sake of example only, without limiting the scope of the disclosure. The reference figures quoted below refer to the attached drawings.

### BRIEF DESCRIPTION OF THE FIGURES

The above, as well as additional, features will be better understood through the following illustrative and non-limiting detailed description of example embodiments, with reference to the appended drawings.

FIG. 1 is a schematic view of a tool for evaluating photoresist chemical changes during lithographic processes, according to example embodiments.

FIG. 2 illustrates a schematic representation of a particular embodiment of the atmosphere control system, according to example embodiments.

FIG. 3 is a comparative view of the system implementation showing integration of EUV exposure, Fourier-transform Infrared (FTIR) spectroscopy module, and bake chamber components in a controlled environment, according to example embodiments.

FIG. 4 is a schematic view of a multi-chamber system for evaluating photoresist chemical changes during lithographic processes, according to example embodiments.

FIG. 5 is a schematic diagram of a multi-chamber system with integrated FTIR and bake processes, according to example embodiments.

FIG. 6 is a schematic cross-sectional view of an intermediate chamber with integrated FTIR capabilities within a multi-chamber processing system, according to example embodiments.

FIG. 7 is a schematic diagram of a bake chamber configured for evaluating photoresist chemical changes during lithographic processes, according to example embodiments.

FIG. 8 is a schematic view of a tool for evaluating photoresist chemical changes during lithographic processes, according to example embodiments.

FIG. 9 is a schematic view of a tool system for evaluating photoresist chemical changes during lithographic processes, according to example embodiments.

FIG. 10 is a flowchart of a method for evaluating photoresist chemical changes during lithographic processes under independently controlled atmospheres, according to example embodiments.

FIG. 11 is a diagram of a system for evaluating photoresist chemical changes during lithographic processes, according to example embodiments.

FIG. 12 is a flowchart of a method for optimizing lithographic process conditions by evaluating chemical changes, correlating with performance metrics, and identifying optimal conditions, according to example embodiments.

FIG. 13 is a schematic representation of chemical processes occurring in photoresist during post coating delay (PCD) and post-exposure delay (PED), according to example embodiments.

FIG. 14 is a schematic representation of model metal oxide resists (MORs) with various counterions used in tool qualification, according to example embodiments.

FIG. 15a and 15b are schematic representations of chemical processes occurring in a metal oxide resist during lithographic processing stages, according to example embodiments.

FIG. 16 is a comparative graphical representation of absorbance spectra showing photoresist stability in controlled versus non-controlled environments, according to example embodiments.

FIG. 17 is a graphical representation of the relationship between delay time and moisture uptake in a photoresist sample during post-exposure delay, according to example embodiments.

FIG. 18 is a graph showing the relationship between post-exposure bake temperature and chemical changes in a photoresist sample, depicting ligand and SnO signals, according to example embodiments.

FIG. 19a is an FTIR spectrum of an unexposed photoresist sample showing characteristic absorption peaks including H₂O absorption at 3400 cm⁻¹, according to example embodiments.

FIG. 19b is a bar chart representation of OH signal levels in photoresist samples at different processing stages, according to example embodiments.

FIG. 20 is a bar chart illustrating the effect of different atmospheric conditions on ligand signal retention after exposure and post-exposure bake, according to example embodiments.

FIG. 21a and 21b are a set of bar charts showing the effects of different post-exposure bake environments and humidity conditions on ligand cleavage and SnO condensation in metal oxide resists, according to example embodiments.

FIGS. 22a, 22b, and 22c are composite diagrams showing chemical analysis of photoresist during lithographic processing via tool, comprising process flow, FTIR spectra, and differential spectra, according to example embodiments.

FIG. 23 is a graph illustrating the relationship between film thickness and exposure dose for a BMOR sample (MOR-[OH] from FIG. 14), showing thickness plateauing around 20 nm and indicating a dose-to-gel threshold, according to example embodiments.

FIG. 24 is a composite view showing a process flow diagram and comparative FTIR spectra demonstrating dose-dependent chemical changes in a BMOR-coated sample before and after EUV exposure, according to example embodiments.

FIG. 25 (left) is a graph depicting the relationship between ligand cleave fraction and exposure dose for a photoresist material, according to example embodiments.

FIG. 25 (right) is a graph depicting the dose-dependent ligand cleavage and moisture reduction, according to example embodiments.

FIG. 26 is a composite view illustrating the effect of post-exposure bake temperature on ligand removal in EUV-exposed metal-organic resist samples, according to example embodiments.

FIG. 27 is a comparative diagram of chemical changes in BMOR and OSMO model resist materials (resp. MOR-[OH] and MOR-[Ac] from FIG. 14) upon radiation exposure as revealed by FTIR spectroscopy, according to example embodiments.

FIG. 28 is a comparative illustration of thermal behavior in BMOR and OSMO model resists showing FTIR spectra and chemical changes after post-exposure bake at different temperatures, according to example embodiments.

FIG. 29a and 29b are a set of graphs showing EUV irradiation effects on counter-ions in MOR materials and resulting acid formation, according to example embodiments.

FIG. 30 is a set of FTIR spectral graphs showing the effect of relative humidity levels during postexposure bake on photoresist chemical composition, according to example embodiments.

FIG. 31a illustrates a schematic of the tool used for the experiments in example 7, and FIG. 31b illustrates molecular structures used in these experiments, according to example embodiments.

FIG. 32 illustrates development contrast curve test results obtained with BMOR where PED/PEB is done at three different atmospheric environments: CA (clean air from fab), N₂, and CO₂, according to example embodiments.

FIG. 33 illustrates dose-to-gel data for the BMOR samples, according to example embodiments.

FIGS. 34a, 34b, and 34c illustrate dose-to-gel data for the OSMO samples, according to example embodiments.

FIG. 35a and 35b illustrate dose-to gel data for the com-MOR samples, according to example embodiments.

FIG. 36 illustrates a table of experimental tests and dose-to-gel (D2G) results related to the differentiation of PED and PEB environment, according to example embodiments.

FIG. 37a illustrates D2G of a commercial MOR (com-MOR) as function of PED/PEB O2 concentration (in N₂) and PEB temperature; and FIG. 37b illustrates D2G of com-MOR as function of PED/PEB O₂ concentration (in N₂) and PEB time, according to example embodiments.

FIG. 38 illustrates a system for maintaining an oxygen environment during PEB of MORs, according to example embodiments.

FIG. 39 illustrates a method for maintaining an oxygen environment during PEB of MORs, according to example embodiments.

In the different figures, the same reference signs refer to the same or analogous elements.

All the figures are schematic, not necessarily to scale, and generally only show parts which are necessary to elucidate example embodiments, wherein other parts may be omitted or merely suggested.

### DETAILED DESCRIPTION

The present disclosure will be described with respect to particular embodiments and with reference to certain drawings but the disclosure is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the example embodiments.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the example embodiments described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the example embodiments described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. The term “comprising” therefore covers the situation where only the stated features are present and the situation where these features and one or more other features are present. Thus, the scope of the expression “a device comprising means A and B” should not be interpreted as being limited to devices consisting only of components A and B. It means that with respect to the example embodiments, the only relevant components of the device are A and B.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of example embodiments, various features of the disclosure are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed embodiments requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate example embodiment.

Furthermore, while some embodiments described herein include some but not other features included in other embodiments, combinations of features of different embodiments are meant to be within the scope of the disclosure, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the example embodiments.

In the description provided herein, numerous specific details are set forth. However, it is understood that embodiments of the present disclosure may be practiced without these specific details. In other instances, well-known methods, structures and techniques have not been shown in detail in order not to obscure an understanding of this description.

The following terms are provided solely to aid in the understanding of the present disclosure.

As used herein, and unless otherwise specified, the term “photoresist sample” refers to any substrate or wafer portion upon which a photoresist film has been applied, including but not limited to semiconductor wafers, glass substrates, or other materials suitable for lithographic processes. Examples of such substrates include silicon wafers used in microfabrication, quartz wafers used in photomask fabrication, or other materials that accept a photoresist coating.

As used herein, and unless otherwise specified, the term “photoresist film” refers to a layer formulated with light-sensitive or radiation-sensitive compounds deposited over a substrate, and intended to undergo chemical or physical changes upon exposure to radiation or after specific process steps. Examples of photoresist films include chemically amplified resists suitable for extreme ultraviolet (EUV) lithography, deep ultraviolet (DUV) lithography, or electron beam lithography, as well as nonchemically amplified resists.

As used herein, and unless otherwise specified, the phrase “radiation exposure station” refers to any subsystem of the tool configured to direct and apply radiation to a photoresist sample. It typically enables control over parameters such as dose, wavelength, and exposure duration. Examples of radiation sources used in such a station include extreme ultraviolet (EUV) light sources, deep ultraviolet (DUV) light sources, electron beam emitters, or (lab-scale) radiation sources such as discharge produced plasma light sources designed to replicate production lithography wavelengths.

As used herein, and unless otherwise specified, the term “stage” refers to any platform or mechanism on which a photoresist sample is placed for positioning, alignment, or movement relative to a radiation beam or measurement beam. Examples of such stages include two-dimensional XY stages enabling precise lateral motion, rotary stages enabling rotation of the sample, or combined XY-rotary stages for multi-axis positioning.

As used herein, and unless otherwise specified, the phrase “thermal processing station” refers to a subsystem of the tool configured to subject a photoresist sample to controlled heating or cooling, thereby enabling processes such as post-exposure bake (PEB), post-application bake (PAB), soft bake, or other temperature-dependent treatments of the photoresist. Examples of thermal processing elements include hot plates designed to reach temperatures from 20° C. up to about 350° C., chill plates for maintaining cool temperatures, and associated sensors to measure environmental parameters such as humidity or gas concentration during the thermal process.

As used herein, and unless otherwise specified, the phrase “intermediate analysis station” refers to a subsystem of the tool separate from other stations, configured for in-process or post-process analysis of the photoresist sample's properties. It comprises a system configured for analyzing photoresist samples. For instance, this station can host measurement instruments for chemical analysis, thickness measurement, optical characterization, or thermal property evaluation. Examples include Fourier Transform Infrared (FTIR) spectrometers, ellipsometers, reflectometers, or other analytical devices.

As used herein, and unless otherwise specified, the phrase “system configured for analyzing photoresist samples” refers to any apparatus or collection of apparatuses intended to measure or detect chemical, optical, physical, or other properties of a photoresist sample. This can be performed, for instance, by spectroscopic, mechanical, or other methods. Examples of such systems include FTIR spectrometers for infrared spectroscopic measurements, ellipsometers for measuring film thickness and optical constants, or mass spectrometry instruments for outgas analysis.

As used herein, and unless otherwise specified, the phrase “sample tilting mechanism” refers to a device or assembly that can adjust the angle of a photoresist sample relative to an incoming beam or radiation or analysis light. An example is a goniometer that allows fine angular positioning of the sample to modify path lengths or angles of incidence, optimizing measurement conditions such as FTIR transmission.

As used herein, and unless otherwise specified, the phrase “environmental isolation means” refers to structures, features, or components designed to preserve distinct atmospheric or vacuum conditions in separate subsystems of the tool, preventing cross-contamination or pressure equalization among them. Examples include valves, gate mechanisms, seals, or isolation chambers arranged to allow sample transfer without compromising the environment in each station.

As used herein, and unless otherwise specified, the phrase “atmosphere control system” refers to a combination of hardware, and optionally software or firmware implementing operational methods, that manage the composition, pressure, humidity, and other environmental characteristics within the tool's stations. Examples of atmospheres provided by such a system include high vacuum, low vacuum, inert gas environments (e.g., nitrogen, argon), reactive gas environments (e.g., oxygen), or controlled humidity environments achieved with devices such as humidity control units or bubblers.

As used herein, and unless otherwise specified, the term “high vacuum” refers to an environment where the pressure is maintained at or below a level on the order of 1×10⁻⁶ mbar or lower, so as to minimize gaseous molecule presence. In contrast, the term “low vacuum” refers to a less stringent vacuum level, typically in the mbar to 10⁻³ mbar range.

As used herein, and unless otherwise specified, the term “clean air (CA)” refers to an environment substantially free from airborne molecular contaminants or particulate matter, maintained through filtration and circulation methods to reduce contamination within a station.

As used herein, and unless otherwise specified, the term “sample transfer system” refers to a subsystem, including but not limited to robotic arms or manual handlers, configured to move a photoresist sample between stations without exposing that sample, or the stations, to undesired environmental changes. Examples include motorized transfer arms coordinated via a central control or manually operated stage-transfer devices, each capable of sealing off or isolating station environments during transport.

As used herein, and unless otherwise specified, the phrase “resist coat station” refers to any subsystem configured to deposit or apply a photoresist material onto a substrate, thereby forming a photoresist film. Examples include spin-on systems using spinning to spread fluid resist solutions evenly over the substrate, and dry deposition systems using vapor-phase or other non-liquid methods to deposit the photoresist.

As used herein, and unless otherwise specified, the phrase “developer station” refers to any subsystem configured to remove exposed or unexposed portions of a photoresist film, depending on whether the resist is positive- or negative-tone, so as to create the desired pattern. Examples include wet systems such as puddle or spin-off development using aqueous or solvent-based developers, as well as dry systems employing plasma processes to selectively etch or remove parts of the resist film.

As used herein, and unless otherwise specified, the phrase “post-application bake (PAB)” refers to a thermal treatment stage conducted after a photoresist film has been applied to a substrate, intended to remove residual solvents, promote adhesion, or achieve partial crosslinking. An example includes placing the freshly coated substrate onto a hot plate at a defined temperature and duration aligned with the resist formulation's recommended bake profile.

As used herein, and unless otherwise specified, the phrase “post-exposure delay (PED)” refers to the time interval between the exposure of the photoresist film to radiation and the subsequent processing step (such as a bake or development), during which the sample may be stored or held under controlled conditions. Examples of controlled conditions include inert atmospheres like nitrogen or vacuum environments intended to minimize undesired chemical changes that could alter the resist profile.

As used herein, and unless otherwise specified, the term “outgas analysis” refers to methods or procedures used to detect and characterize gaseous species released from a photoresist film during or after exposure or thermal treatment. An example includes monitoring by a residual gas analyzer (RGA) to identify volatile byproducts or contaminants.

As used herein, and unless otherwise specified, the term “thermal desorption analysis” refers to measuring substances that emerge from a photoresist film or substrate during heating, typically by increasing temperature and detecting the outgassed components. An example includes connecting a heated chamber to a mass spectrometer, such as a residual gas analyzer (RGA), so that substances released at each temperature ramp can be identified.

As used herein, and unless otherwise specified, the term “residual gas analyzer (RGA)” refers to an instrument that detects and measures partial pressures of gases and vapors in a vacuum environment, enabling identification of chemical species outgassing from a photoresist film. An example includes a quadrupole mass spectrometer capable of analyzing gas composition in real time during exposure or thermal processing.

As used herein, and unless otherwise specified, the phrase “temperature-controlled stage” refers to a platform on which a photoresist sample is placed that can regulate temperature to a desired setpoint. Examples include chill plates configured to cool substrates for stabilizing their properties, as well as heated stages maintaining a constant elevated temperature during analysis.

As used herein, and unless otherwise specified, the phrase “chill plate” refers to a specific type of temperature-controlled stage designed to lower or stabilize the temperature of a photoresist sample, typically to lessen thermal diffusion or unwanted chemical changes before, during, or after measurement. An example might be a refrigerant-based plate capable of maintaining sub-ambient temperatures.

As used herein, and unless otherwise specified, the term “hot plate” refers to a heating apparatus for raising the temperature of a photoresist sample within a controlled range, typically from room temperature up to an upper setpoint. Examples include conduction-based plates with embedded heaters, or contactless thermal systems with precisely regulated heat transfer surfaces.

As used herein, and unless otherwise specified, the term “humidity control unit” refers to a device that adjusts and controls the level of water vapor present in a station's atmosphere. An example includes a bubbler that passes a carrier gas through water to achieve a defined relative humidity (RH), thereby allowing processes to be carried out under controlled moisture conditions.

As used herein, and unless otherwise specified, the phrase “airborne molecular contaminants (AMCs)” refers to gaseous or vapor-phase impurities that can chemically react with or otherwise affect a photoresist film, such as amines or volatile organic compounds (VOCs). Examples include ammonia, diisopropylamine, or other basic compounds that may cause photoresist deprotection, as well as volatile organics that may deposit or alter the resist surface. Other examples include oxidizing and reactive compounds (e.g., H₂O, CO₂, NH₃, etc.), which may be more relevant for MOR materials.

As used herein, and unless otherwise specified, the phrase “controller” refers to a computing device or collection of computing resources arranged for carrying out at least some steps of the method. This may include coordinating sample transfers, controlling environmental parameters, executing method steps measurement, and/or executing processing sequences. Examples include a programmable logic controller (PLC), a personal computer running dedicated software, or an integrated control system configured to handle lithographic process recipes.

### Overview

The present disclosure will now be described by a detailed description of several example embodiments. It is clear that other example embodiments can be configured according to the knowledge of persons skilled in the art without departing from the technical teaching of the disclosure, the example embodiments being limited only by the terms of the appended claims.

In a first aspect, the present disclosure relates to a tool 10 for evaluating photoresist chemical changes during lithographic processes. This tool 10 comprises a radiation exposure station 20 for exposing photoresist samples 15 to radiation; a thermal processing station 30 for thermally processing photoresist samples 15; and an intermediate analysis station 40 separate from the exposure station 20 and the thermal processing station 30. The intermediate analysis station 40 comprises a system 42 configured for analyzing photoresist samples 15, and environmental isolation means 60 between the stations enabling independent environments in each station during operation. The tool 10 also includes an atmosphere control system 70 configured to establish different atmospheric conditions in each station, and a sample transfer system 80 for transferring photoresist samples 15 between the stations while maintaining environmental isolation.

FIG. 1 illustrates a schematic view of an embodiment of this tool 10 for evaluating photoresist chemical changes during lithographic processes. The depicted embodiment of the tool 10 comprises three main stations: a radiation exposure station 20 (here with measurement capabilities), an intermediate analysis station 40, and a thermal processing station 30. Each station is connected by a sample transfer system (here transfer arms) 80 for moving the photoresist samples 15 between them while maintaining environmental isolation. The radiation exposure station 20 includes an optional sample stage for holding the photoresist sample 15 and, in the depicted embodiment, is equipped with an optional in-situ measurement system 170, such as a residual gas analyzer (RGA) for monitoring outgassing during exposure. The radiation exposure station is designed to expose the sample to radiation, such as EUV, under a controlled environment. The intermediate analysis station 40 features an optional chill plate 150 to cool down the sample and/or maintain a constant sample temperature until the start of analysis. It is equipped with system 42 configured for analyzing photoresist samples 15. For instance, it can be equipped with a Fourier Transform Infrared (FTIR) spectrometer 42 for analyzing the chemical changes in the photoresist. The station can be purged with an inert gas or maintained under vacuum to suppress atmospheric absorption peaks.

In embodiments, the measurement chamber of the intermediate analysis station may be arranged to alternately expose a sample to at least two different atmospheres and to perform spectroscopic analysis after each atmosphere change. For instance, the intermediate analysis station may comprise gas in- and outlets, a vacuum pump, and automated valves that may permit sequential switching between a vacuum condition and a selected gas condition without opening the station to ambient air. This may permit controlled, repeatable simulation of real-world post-exposure delay conditions without removing the sample 15 from the protected cluster environment. In example embodiments, this is performed while the sample remains thermally stabilized, for instance within ±1° C. As an example, in the intermediate analysis station 40, a programmable valve manifold may switch the chamber between ≤1×10⁻¹ mbar and a nitrogen atmosphere at 45% RH in cycles of not more than 2 minutes, each cycle being followed by an FTIR transmission measurement on the sample 15 held at 20° C., thereby enabling time-resolved studies of post-exposure delay phenomena.

The thermal processing station 30 typically contains a hot plate for thermally processing the samples 15, for instance, at temperatures between 20° C. and 300° C. It may include sensors 34 for measuring environmental parameters such as humidity and gas concentration. The station may be configured for in-situ analysis of the photoresist sample 15 during thermal processing, for instance by enabling outgas analysis and/or FTIR spectroscopy.

Environmental isolation means 60 are positioned between each of the stations, allowing for independent environments in each station during operation. An atmosphere control system 70 is configured to establish different atmospheric conditions in each station. Such atmospheric conditions may for instance be high vacuum, low vacuum, clean air (CA), and various gases. The entire setup may be under a controlled environment to ensure precise evaluation of photoresist chemical changes.

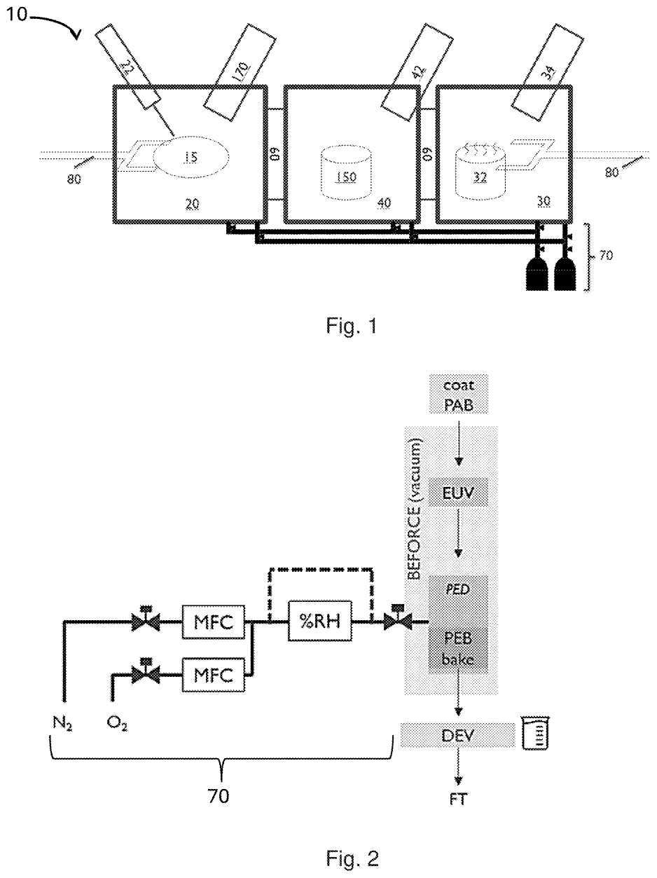

FIG. 2 illustrates a schematic representation of a particular embodiment of the atmosphere control system 70, specifically designed to enable precise control over the atmospheric environment during post-exposure delay (PED) and post-exposure bake (PEB) steps. The diagram on the right shows the context within the overall lithographic workflow, indicating that after the EUV exposure step is performed in vacuum within the tool 10, the sample is subjected to PED and PEB under the controlled atmosphere provided by this system.

As shown in the diagram on the left of FIG. 2, the system may be configured to mix multiple gases to create a desired process atmosphere. In this embodiment, input lines for a carrier or inert gas, such as nitrogen (N₂), and a reactive gas, such as oxygen (O₂), are provided. Each gas line may be equipped with a valve for on/off control and a mass flow controller (MFC) for precisely regulating the flow rate of the respective gas. By adjusting the setpoints of the MFCs, a gas mixture with a predetermined and repeatable ratio of oxygen to nitrogen can be created, allowing for the study of environments ranging from fully inert to oxygen-rich.

Downstream of the gas mixing point, the combined gas stream may be passed through a humidity control unit (% RH), such as a humidifier 224, to introduce a controlled amount of water vapor and achieve a target relative humidity. In embodiments where a completely dry atmosphere is required (e.g., 0% RH), a bypass line (dashed line), which may be manually or automatically controlled, can be included to route the gas mixture around the humidity control unit. This ensures that a true dry condition can be achieved without residual moisture from the humidity control unit affecting the process. A final valve controls the delivery of the fully conditioned gas mixture into the appropriate station of the tool 10, such as the thermal processing station 30 or intermediate analysis station 40, where the PED or PEB steps are performed.

This embodiment of the atmosphere control system 70 may allow for executing the methods of example embodiments. It allows for the systematic evaluation of how reactive gases (e.g., oxygen) and humidity levels during post-exposure processing steps affect the photoresist's chemical transformations, such as ligand cleavage and network condensation. The controller 300 may be configured to automate the operation of the valves and MFCs to execute pre-programmed recipes, ensuring high precision and repeatability for experiments designed to optimize lithographic process conditions.

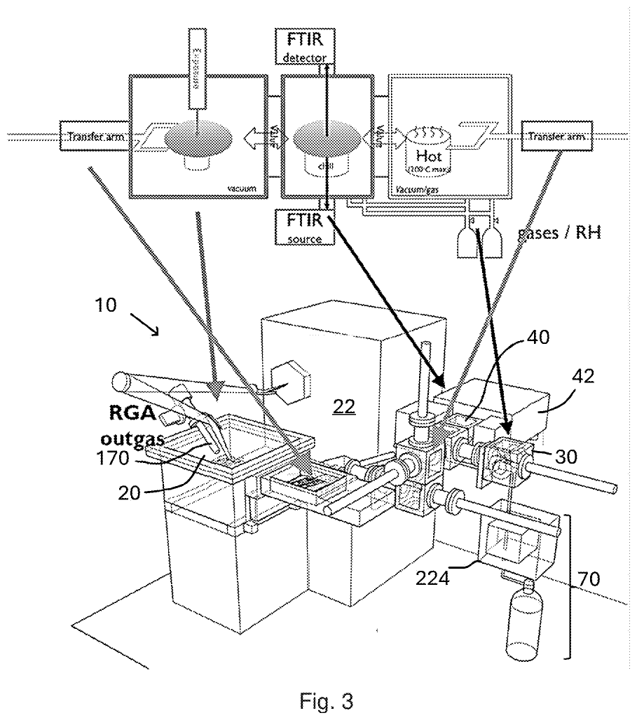

To provide a more concrete illustration of the example embodiments, a specific embodiment of the tool 10 will now be described in detail. This embodiment corresponds to the system used to generate the data in the Examples section that follows and is illustrated in FIGS. 3 to 7.

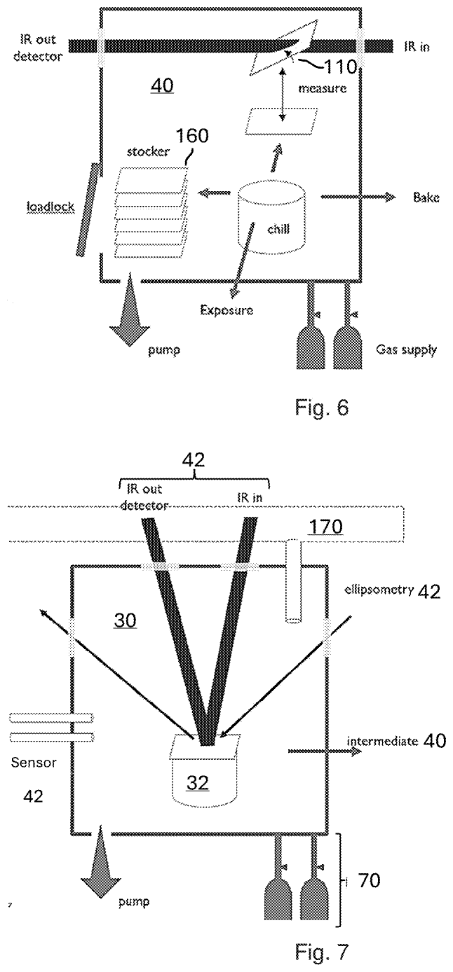

The multi-chamber design of this embodiment is shown schematically in the top section of FIG. 3. The tool 10 comprises three primary chambers connected in sequence: a radiation exposure station 20, an intermediate analysis station 40, and a thermal processing station 30. The first station 20 contains a sample stage for exposing a photoresist sample 15 to a radiation source 22 under vacuum conditions. The second, intermediate station 40 features an optional chill plate 150 for temperature stabilization and is equipped with a system 42 configured for analysis, here an FTIR spectrometer with a source and detector for in-situ measurements. The third station 30 includes a hot plate 32 for thermal processing up to 300° C. and is equipped with connections for the atmosphere control system 70 to introduce controlled gases and humidity. Each station is separated by valves 60, enabling independent environmental control and ensuring the sample remains in a controlled atmosphere throughout processing and analysis. While the simplified illustration in FIG. 3 (top) shows the sample on the chill plate during measurement, in this embodiment the analysis is performed away from the chill plate and the system 42 further comprises a sample tilting mechanism 110 as depicted in FIG. 6.

The physical implementation of this integrated tool 10 is shown in FIG. 3. This system may include an EUV exposure chamber with an EUV source, a sample entry loadlock, and a residual gas analyzer (RGA) 170 for outgas measurement. FIG. 3 (bottom) shows the 3D model of the fully integrated tool 10 according to example embodiments. The original radiation exposure station 20 has been extended with the addition of the intermediate analysis station 40, which contains the FTIR module 42, and the thermal processing station 30 for controlled baking.

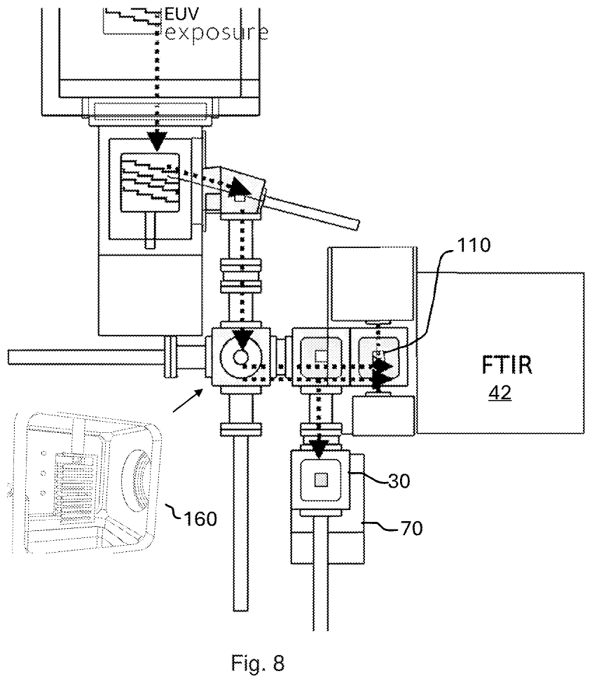

The sample handling pathways of this embodiment is further illustrated in the top view of FIG. 8. FIG. 3 (bottom) and FIG. 8 show a modular configuration where the stations are connected by cylindrical conduits, enabling sequential processing. The top-down view in FIG. 8 illustrates a potential sample path, wherein a sample 15 is transferred from a multi-sample holder in the exposure station 20 to a sample storage unit or garage 160 located within the intermediate station 40, and then moved to the analysis position before proceeding to the thermal processing station 30. The integration of the FTIR spectrometer 42 with a goniometer 110 for sample tilting is highlighted in FIG. 8. This setup optimizes the optical path length for transmission measurements. The integration of the atmosphere control system 70 with the bake chamber 30 is also shown in these figures, which details the connections for bulk gases and the humidity control unit 224 for precise humidity control.

Further details of the individual chambers of this embodiment are provided in FIGS. 5 to 7. FIG. 5 shows a schematic of the complete three-chamber system, indicating the placement of FTIR components, outgas analysis ports 170, sample stages (chill stage 150, hot stage), and transfer arms 80. A detailed view of the intermediate analysis station 40 is provided in FIG. 6. It shows the arrangement of the FTIR system 42, the goniometer 110 for tilting the sample 15, the chill plate 150, and the sample stocker 160 for holding multiple samples. A detailed schematic of the thermal processing station 30 is shown in FIG. 7, illustrating the bake stage, integrated in-situ FTIR and optional ellipsometry capabilities, outgas analysis port 170, and sensors 34 for monitoring humidity and gas concentration.

In embodiments, the atmosphere control system 70 may be arranged to deliver predetermined quantities of reactive trace gases in addition to bulk gases to any station of the tool 10. This capability may allow systematic evaluation of resist sensitivity to airborne molecular contaminants (AMCs). In embodiments, the atmosphere control system 70 may comprise mass-flow-controlled lines for different gases (e.g., for NO and NO₂). In embodiments, atmosphere control system 70 may have dilution capability down to sub-ppm levels. In embodiments, the atmosphere control system 70 may comprise an exhaust scrubber to prevent cross-contamination of neighboring chambers. As an example, during post-exposure bake, the bake chamber 30 may receive a 100 ppm O₂/N₂ mixture at 1 bar and 30% RH for 60 s, after which the chamber may be purged with dry N₂; inline electro-chemical sensors may verify O₂ concentration within ±10 ppm.

The radiation exposure station 20 may be configured to expose photoresist samples 15 to radiation selected from the group consisting of extreme ultraviolet radiation, deep ultraviolet radiation, and an electron beam. This allows for compatibility with different lithography technologies.

The radiation exposure station 20 may comprise a radiation source, such as a discharge produced plasma light source. In example embodiments, the radiation source is for generating radiation having the same wavelength as used in production lithography tools. This enables realistic simulation of production conditions in a research environment.

The radiation exposure station 20 may comprise a stage, such as an XY or rotary stage, for positioning the photoresist sample 15 to allow for multiple exposure conditions on a single sample 15. This increases efficiency by allowing multiple test conditions on a single sample 15.

The system configured for analyzing photoresist samples in the intermediate analysis station 40 may comprise a Fourier Transform Infrared (FTIR) spectrometer 42. This provides detailed molecular-level analysis of chemical changes in the photoresist.

The system configured for analyzing photoresist samples 42 may be configured for FTIR spectrometry transmission measurements through a photoresist sample 15. This allows for more accurate analysis of chemical changes throughout the entire thickness of the film.

The system 42 configured for analyzing photoresist samples 15 may further comprise a sample tilting mechanism, such as a goniometer 110, for tilting the photoresist sample 15 to increase the optical path length for transmission measurements. This improves signal-to-noise ratio and measurement sensitivity for thin films.

As shown in FIG. 8, this schematic illustrates the configuration for adjusting the orientation of a sample 15 to the infrared (IR) beam using a goniometer 110. The standard IR beam is depicted entering the system, where the goniometer 110 is employed to precisely align the sample 15 for optimal IR beam interaction. The schematic also indicates a potential upgrade path to enable FTIR measurements during the bake process, as shown by a dashed line leading to a designated area.

FIG. 6 illustrates an intermediate chamber with several key components and functionalities. At the top, an “IR in” source and an “IR out” detector 42 are shown, indicating the path of the infrared beam used for analysis. A sample 15 is positioned on a stage, which is tilted using a goniometer 110 to increase the optical path length for transmission measurements.

The atmosphere control system 70 may be configured to purge the intermediate analysis station 40 with an inert gas or to maintain it under vacuum during measurements to suppress atmospheric absorption peaks. This reduces interference from atmospheric components and improves measurement accuracy. This is particularly relevant for FTIR measurements.

The intermediate analysis station 40 may further comprise an ellipsometer. This enables additional film thickness and optical property measurements.

The intermediate analysis station 40 may comprise a temperature-controlled stage 150. This ensures consistent measurement conditions by preventing temperature-induced variations.

The temperature-controlled stage 150 may be a chill plate 150 configured to maintain a constant sample temperature until the start of an analysis. This provides temperature stability for accurate and reproducible measurements. The analysis itself may be performed away from the temperature-controlled stage 150. The sample may be returned to the temperature-controlled stage 150 between analysis.

The thermal processing station 30 may comprise a hot plate configured to heat samples 15 to a temperature between 20° C. and 300° C. This allows for simulation of the full range of post-exposure bake conditions used in production.

In embodiments, the thermal processing station 30 may be capable of heating a substrate to a temperature of at least 300° C. In embodiments, the thermal processing station 30 may comprise a radiative or inductive heater enabling heating. In embodiments, the atmosphere control system may comprise a gas manifold for supplying inert or reducing gases at pressures between 5 Pa and atmospheric pressure, to the thermal processing station 30. In embodiments, the thermal processing station 30 may comprise optical ports for in-situ spectroscopic monitoring. As an example, the thermal processing station may be fitted with IR-transparent sapphire windows that allow in-situ FTIR reflection measurements and residual-gas analysis of desorbed hydrocarbons.

The thermal processing station 30 may comprise sensors 34 for measuring environmental parameters such as humidity and gas concentration. This enables precise monitoring and control of the processing environment.

The thermal processing station 30 may be configured for in-situ analysis of the photoresist sample 15 during thermal processing. The analysis may, for instance, be selected from the group consisting of outgas analysis, thermal desorption analysis, FTIR spectroscopy, and ellipsometry. This allows real-time monitoring of chemical changes during thermal processing.

The environmental isolation means 60 may comprise valves positioned between each of the stations. This provides effective isolation between different environments to prevent cross-contamination.

The tool 10 may further comprise a sample storage unit 160, e.g., in the intermediate analysis station 40, such as a garage or stocker 160, connected to the sample transfer system 80 for holding one or more samples 15 under a controlled environment. This enables time-delay studies under controlled conditions.

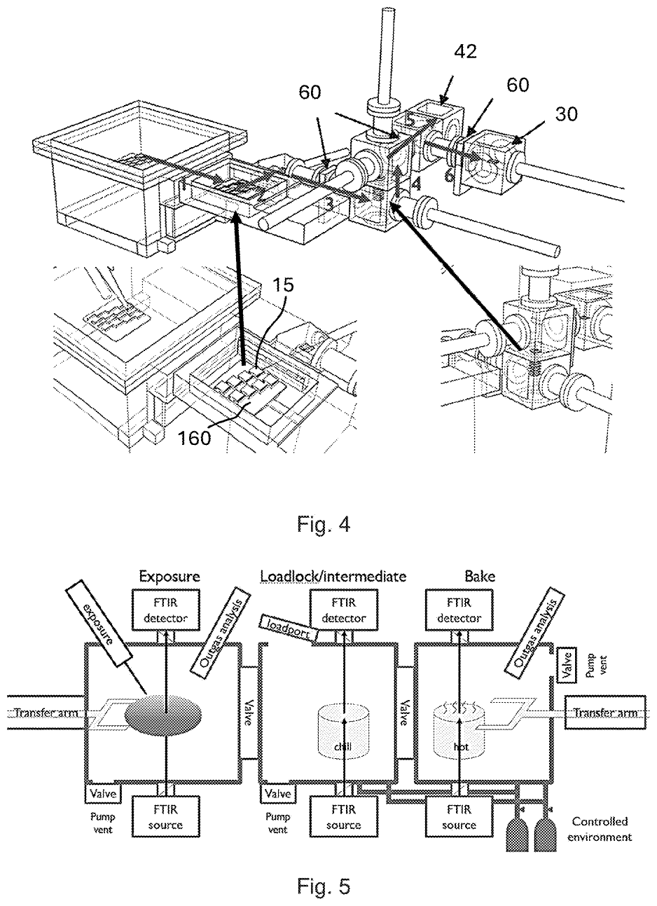

As shown in FIG. 4, the system includes a sample table for the exposure of multiple samples and a sample store unit 160 for stacking multiple samples 15. The system is equipped with a series of valves 60 that provide environmental isolation between the chambers, allowing for independent atmospheric conditions in each section. The sample store unit 160 is also shown in FIG. 6 where a sample storage unit 160 is shown on the left, here within the intermediate station 40, capable of holding multiple wafer samples 15, with one sample 15 being moved from the sample store unit 160 to the chill plate 150.

The radiation exposure station 20 may further comprise a residual gas analyzer (RGA) 170 for monitoring outgassing from the photoresist sample 15 during exposure. This provides insight into volatile reaction products during exposure.

The atmosphere control system 70 may be configured to independently provide in any of the stations, atmospheres selected from the group consisting of high vacuum, low vacuum, clean air (CA), carbon dioxide (CO₂), oxygen (O₂), inert gases such as nitrogen (N₂), and mixtures thereof. This allows testing under a wide range of environmental conditions.

The atmosphere control system 70 may be configured to provide a gas environment comprising oxygen to one or more of the stations. This enables studies of oxygen effects on resist chemistry, particularly important for metal oxide resists.

In embodiments, the atmosphere control system 70 may comprise:
at least a first gas inlet for an inert gas (e.g., N₂) and a second gas inlet for a reactive gas (e.g., O₂); and
a mass flow controller (MFC) connected to each of the first and second gas inlets, wherein the mass flow controllers are configured to independently control the flow rate of each gas to create a gas mixture with a predetermined composition for introduction into one of the stations (e.g., into the intermediate analysis station and/or into the thermal processing station).

The atmosphere control system 70 may further comprise a humidity control unit 224 for controlling relative humidity (RH) within one or more stations. This enables studies of moisture effects on resist chemistry. Such a humidity control unit is visible in FIG. 3.

In embodiments, the atmosphere control system 70 may further comprise:
a humidity control unit 224 positioned downstream of the mass flow controllers, configured to receive the gas mixture and introduce a controlled amount of humidity; and
a bypass line configured to selectively route the gas mixture around the humidity control unit to provide a dry atmosphere to one of the stations.

The atmosphere control system 70 may be configured to provide an inert gas, not interfering with the analysis, to the intermediate analysis station 40. This minimizes interference during analytical measurements.

The atmosphere control system 70 may be configured to provide a high vacuum environment below 1×10⁻⁶ mbar in the radiation exposure station 20. This simulates the vacuum conditions of production EUV exposure tools.

The atmosphere control system 70 may be further configured to dose controlled amounts of airborne molecular contaminants (AMCs), such as amines or volatile organic compounds (VOCs). This allows investigation of contaminant effects on resist performance.

The sample transfer system 80 may comprise one or more transfer arms 80 configured for manual or automated transfer of samples 15. This provides flexibility in operation and sample handling.

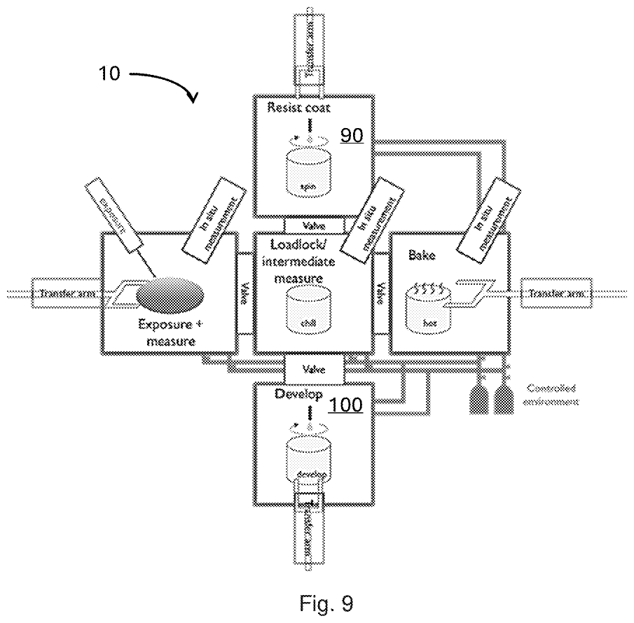

The tool 10 may further comprise a resist coat station 90 connected to the sample transfer system 80, the resist coat station 90 configured for applying a photoresist film to a sample 15. This enables a more complete process flow study from the coating on. A tool comprising such a resist coat station is depicted in FIG. 9.

The resist coat station 90 may be a spin-on system or a dry deposition system. This accommodates different types of resist application methods.

The tool 10 may further comprise a developer station 100 connected to the sample transfer system 80, the developer station 100 being configured for developing an exposed photoresist film. This allows complete end-to-end process evaluation. A developer station 100 is also visible in FIG. 9.

The developer station 100 may be a wet system for puddle and spin-off development or a dry system using a thermal and/or plasma-based process. This supports both traditional and advanced development techniques.

When both a resist coat station 90 and a developer station 100 is present in the tool 10, the intermediate analysis station 40 may be centrally located so as to enable a direct connection to every other station. This allows the intermediate analysis station 40 to serve as a hub for transferring samples 15 between different processing stages.

In FIG. 9 is illustrated a comprehensive tool 10 for evaluating photoresist chemical changes during lithographic processes, incorporating a resist coat station 90 and a developer station 100. The system is designed to maintain a controlled environment throughout the process. The tool 10 comprises several interconnected stations, each serving a specific function in the lithographic process. The exposure and measurement station 20 is depicted on the left, where a sample 15 is exposed to radiation. This station 20 is connected to a loadlock/intermediate analysis station 40, which includes an optional chill plate 150 for stabilizing the sample 15 temperature. The intermediate analysis station 40 is, in this example embodiment, centrally located and serves as a hub for transferring samples 15 between different processing stages. Above the intermediate station 40 is the resist coat station 90 connected to the sample transfer system 80, which applies a photoresist layer to the sample 15. In the depicted embodiment, this station 80 is equipped with an optional spin-on system for resist application. Below the intermediate station 40 is the develop station, which processes the exposed photoresist. This station can handle both wet and dry development processes. To the right of the intermediate station 40 is the thermal processing station 30, featuring an optional hot plate for post-exposure baking. This station 30 may allow for inducing chemical changes in the photoresist after exposure. Transfer arms of a sample transfer system 80 are depicted on either side of the system 10, facilitating the movement of samples 15 between stations while maintaining environmental isolation. Environmental isolation means (e.g., valves 60) are placed between stations to ensure independent atmospheric conditions can be maintained in each chamber.

Any feature of the first aspect may be as correspondingly described in any of the other aspects.

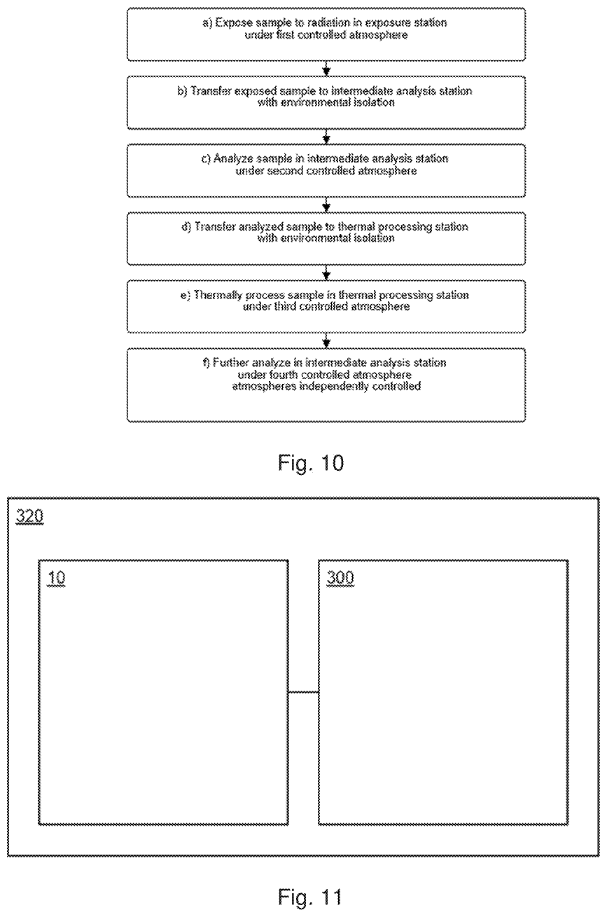

In a second aspect, the present disclosure relates to a method for evaluating photoresist chemical changes during lithographic processes in a tool 10 according to the first aspect. As illustrated in FIG. 10, this method comprises exposing a photoresist sample 15 to radiation in the radiation exposure station 20 under a first controlled atmosphere; transferring the exposed photoresist sample 15 to the intermediate analysis station 40 while maintaining environmental isolation; performing analysis of the photoresist sample 15 in the intermediate analysis station 40 under a second controlled atmosphere; transferring the analyzed sample 15 to the thermal processing station 30 while maintaining environmental isolation; thermally processing the photoresist sample 15 in the thermal processing station 30 under a third controlled atmosphere; and transferring the thermally processed sample 15 back to the intermediate analysis station 40 while maintaining environmental isolation, and performing further analysis of the photoresist sample 15 in the intermediate analysis station 40 under a fourth controlled atmosphere, wherein the first, second, third, and fourth controlled atmospheres are independently controlled.

Performing analysis in the method may comprise performing Fourier Transform Infrared spectroscopy 42 in a transmission mode. This provides detailed molecular information about chemical changes in the resist.

The second and fourth controlled atmospheres may be selected from the group consisting of an inert gas atmosphere and a vacuum to minimize interference with the analysis. This ensures measurement accuracy by reducing environmental interference.

The third controlled atmosphere may comprise a reactive gas, such as oxygen, and/or a controlled level of humidity. This allows investigation of specific environmental effects on thermal processing.

In embodiments, providing the third controlled atmosphere for the thermal processing step (e) may comprise:
independently controlling the flow rates of at least a first gas and a second gas using respective mass flow controllers to create a gas mixture with a predetermined ratio; and
introducing the gas mixture into the thermal processing station 30. In embodiments, the first gas may be an inert gas, such as nitrogen, and the second gas may be a reactive gas, such as oxygen. In embodiments, the thermal processing station 30 may further comprise one or more gas sensors 34 for providing real-time information on the concentration of specific atmospheric components, such as O₂ or H₂O. this permits to verify and actively control the composition of the third controlled atmosphere. In embodiments, this data can be used by the controller 300 in a feedback loop to dynamically adjust the mass flow controllers, ensuring the atmospheric composition is maintained at a precise setpoint throughout the thermal processing step. In embodiments, the method may further comprise, before introducing the gas mixture into the thermal processing station 30, selectively performing one of the following steps:
passing the gas mixture through a humidity control unit to achieve a predetermined relative humidity; or
routing the gas mixture through a bypass line that circumvents the humidity control unit to provide an atmosphere with substantially zero relative humidity.

The method may further comprise monitoring outgassing from the photoresist sample 15 using a residual gas analyzer (RGA) 170 during the exposing step. This provides additional information about volatile reaction products.

The method may further comprise, after transferring to the intermediate analysis station 40 and before performing analysis, storing the exposed photoresist sample 15 in a sample storage unit 160 for a defined post-exposure delay period under a controlled delay atmosphere. This enables controlled investigation of delay effects.

This is exemplified in example 1.

The method may further comprise, before exposing, coating a sample 15 with a photoresist in a resist coat station 90 connected to the sample transfer system 80; transferring the coated sample 15 to the thermal processing station 30; and performing a post-application bake on the coated sample 15. This enables a more complete process flow evaluation from the coating on.

The method may further comprise, after performing the further analysis of step g, transferring the sample 15 to a developer station; and developing the photoresist. This enables evaluation of the final patterning results.

Any feature of the second aspect may be as correspondingly described in any of the other aspects.

In a third aspect, the present disclosure relates to a system 320 comprising the tool 10 according to any embodiment of the first aspect, and a controller 300 for carrying out at least some steps of the method according to any embodiment of the second aspect.

As shown in FIG. 11, this illustrates a diagram of a system 320 for evaluating photoresist chemical changes during lithographic processes. The system 320 comprises two main components: a tool 10 and a controller 300. The tool 10 is depicted as a rectangular block on the left side of the figure, while the controller 300 is shown as a separate rectangular block on the right side. A connecting line between the two blocks indicates a communication or control link. The entire setup is enclosed within a larger rectangular boundary, representing the system 320 as a whole.

The controller 300 may be configured to automate the transfer of photoresist samples 15 and the execution of a pre-programmed sequence of exposing, analyzing, and thermal processing steps. This improves reproducibility and efficiency of experiments.

The controller 300 may be configured to record analysis data from the analysis system 42 and correlate the data with the controlled atmospheres and processing parameters of each step. This enables comprehensive data analysis and process optimization.

The controller 30 may be configured to pilot the atmosphere control system 70 to independently provide in any of the stations, atmospheres selected from the group consisting of high vacuum, low vacuum, clean air (CA), carbon dioxide (CO₂), oxygen (O₂), inert gases such as nitrogen (N₂), and mixtures thereof.

The controller 300 may be configured to pilot the atmosphere control system 70 to maintain the oxygen at a controlled concentration in the one or more of the stations during at least one postexposure thermal processing step. This improves contrast and reduces EUV dose requirements for metal oxide photoresists.

Any feature of the third aspect may be as correspondingly described in any of the other aspects.

In a fourth aspect, the present disclosure relates to a computer program comprising instructions which, when executed by the controller 300 of the system 320 of the third aspect, cause the controller 300 to carry out the method according to the second aspect.

Any feature of the fourth aspect may be as correspondingly described in any of the other aspects.

In a fifth aspect, the present disclosure relates to a computer-readable medium having stored thereon the computer program of the fourth aspect.

Any feature of the fifth aspect may be as correspondingly described in any of the other aspects.

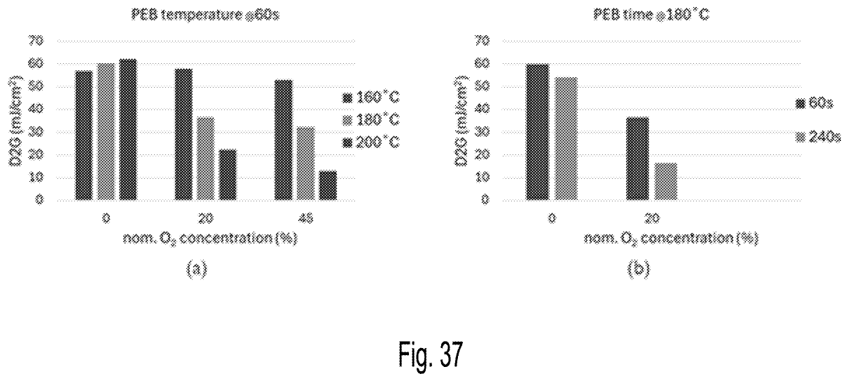

In a sixth aspect, the present disclosure relates to a method for optimizing lithographic process conditions for a photoresist material. As illustrated in FIG. 37a and 37b, this method comprises evaluating photoresist chemical changes using any embodiment of the method of the second aspect under multiple sets of process conditions; correlating the photoresist chemical changes with lithographic performance metrics; and identifying optimal process conditions based on the correlations.

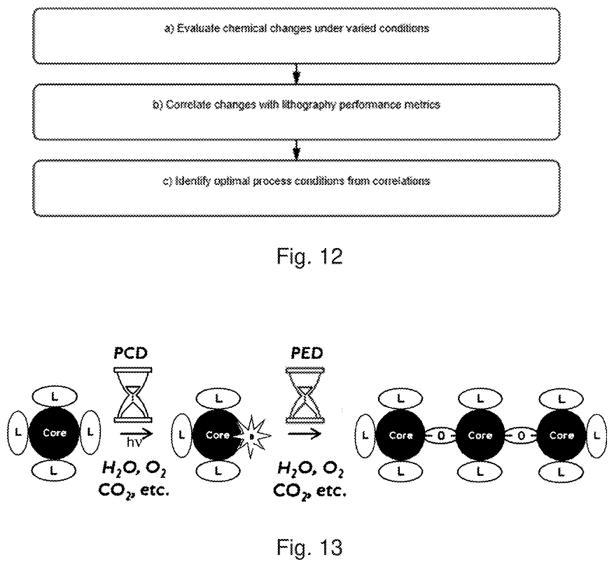

FIG. 12 illustrates a flowchart detailing the method for optimizing lithographic process conditions for a photoresist material. The process begins with evaluating chemical changes under varied conditions, as indicated in step (a). This is followed by correlating these changes with lithography performance metrics, as shown in step (b). Finally, step (c) involves identifying optimal process conditions based on the correlations.

The lithographic performance metrics may be selected from the group consisting of critical dimension, CD uniformity, line-edge roughness, line-width roughness, and stochastic failures. This focuses optimization on industrially relevant performance parameters.

The evaluating step may be performed by varying at least one parameter selected from the group consisting of radiation exposure dose, thermal processing temperature, thermal processing duration, post-exposure delay duration, and the composition and humidity of the first, second, third, and fourth controlled atmospheres, enabling comprehensive process window exploration and optimization.

### EXAMPLES

The following examples illustrate the use and capabilities of the tool (10) of the present disclosure. The experiments demonstrate how the integrated, controlled-environment system enables an unprecedented level of insight into the complex chemical transformations of advanced photoresist materials during lithographic processing.

Metal Oxide Resists (MORs) represent a significant advancement in semiconductor lithography, offering the potential for high-resolution patterning required for next-generation integrated circuits. The excellent lithographic performance of these materials allows achieving precise high-resolution patterning. Achieving this consistently in a manufacturing environment requires a deep understanding of the underlying resist chemistry.

The high performance of MORs is rooted in a complex series of chemical transformations. As illustrated in the reaction diagrams of FIG. 13, MORs can consist of a central metal-oxo core or cage surrounded by organic ligands. During the lithographic process, exposure to radiation initiates photoreactions that lead to condensation, forming a robust, cross-linked network.

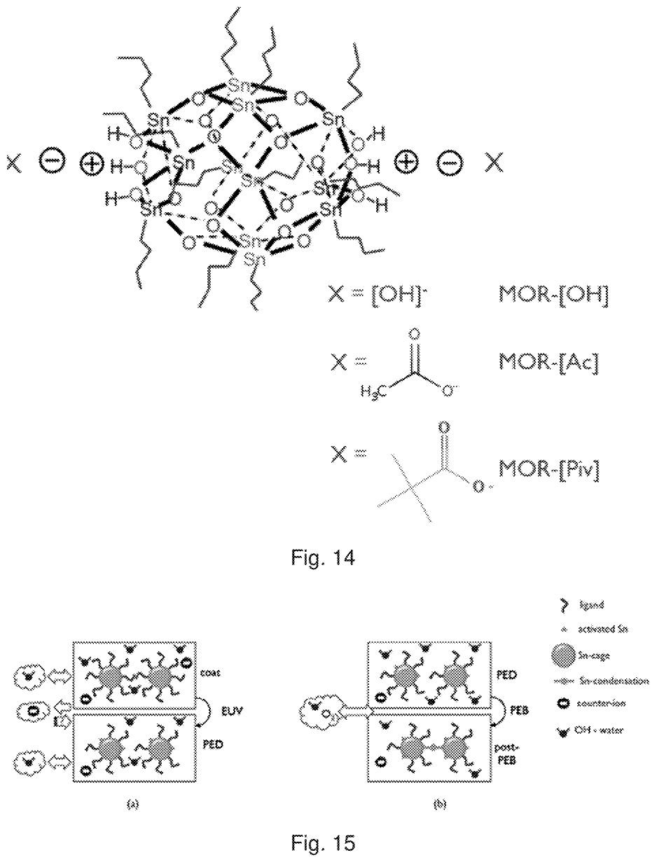

A critical challenge in working with MORs is their pronounced sensitivity to the surrounding atmospheric environment at multiple stages of the process. The Sn-oxo cage structure of a model MOR (see FIG. 14) can readily interact with ambient molecules, particularly water (H₂O). This sensitivity impacts the entire lithographic workflow, as depicted schematically in FIG. 15a and 15b, which shows the evolution of the MOR from its initial coated state, through activation by EUV radiation, and finally to condensation during the post-exposure bake (PEB) phase.

The necessity of specific environmental conditions for successful MOR processing is further emphasized by the fact that, after initial activation by light, the MOR units can be held in a stable state in a vacuum environment, but the critical solid-phase condensation step to form the final oxo-network requires the presence of components from cleanroom air. Similarly, FIG. 15a and 15b highlight the importance of the PEB atmosphere, showing how an oxygen-rich environment is crucial for facilitating further 10 chemical reactions and enhancing the crosslinking of the MOR units after the initial exposure. These examples underscore that the environment is not merely a source of contamination but can be an essential reactant in the desired chemical pathway.

Conventional analytical approaches, which rely on separate, standalone tools for exposure, baking, and measurement, fail to capture these dynamic changes.

The conventional photoresist process begins with the spin-coating of a resist layer onto a silicon wafer, forming a film. This is followed by the exposure step, where extreme ultraviolet (EUV) light is reflected off of a multilayer mask on a low thermal expansion substrate to pattern the resist 15. This step can be assisted by subsequent bake. The development step comes next, showing two possible outcomes: in a positive tone process, the exposed resist 15 is removed, while in a negative tone process, the unexposed resist 15 is removed. The final step is etching, where the patterned resist 15 protects the underlying film during the etching process, resulting in the desired pattern on the silicon substrate.

Transferring a sample between different tools inevitably exposes it to uncontrolled cleanroom ambients, altering its chemical state and making it impossible to distinguish the effects of a specific process step from the effects of environmental exposure. This creates a critical gap in understanding and optimizing MOR process conditions.

To overcome these limitations, the experiments described herein were performed using the tool 10 of the example embodiments. As illustrated in the schematic in FIG. 3 (top), the tool provides a comprehensive, multi-chamber platform designed for step-by-step lithographic processing and analysis.

The system comprises three main stations—a radiation exposure station 20, an intermediate analysis station 40 equipped with a Fourier Transform Infrared (FTIR) spectrometer, and a thermal processing station 30—all connected by a sample transfer system 80. Environmental isolation means 60 and a comprehensive atmosphere control system 70 allow for independent, precisely defined atmospheric conditions (e.g., high vacuum, inert gas, controlled humidity, reactive gases) to be maintained in each station. This integrated design allows, for the first time, a photoresist sample to undergo sequential processing and analysis steps without being exposed to uncontrolled ambient conditions, enabling a direct and unambiguous investigation of molecular transformations as they occur at each stage of the lithographic process.

The capabilities of the tool 10 are demonstrated in the following experimental case studies using several model photoresist systems. The primary focus is on tin-oxo based MORs with various counter-ions, whose molecular structures are shown in FIG. 14, including MOR-[OH], MOR-[Ac], and MOR-[Piv]. While MORs are the main subject, it is noted that the tool is equally suited for studying other advanced material platforms, such as the Chemically Amplified Resists (CARs), showcasing the versatility of the tool 10. The chemically amplified resist (CAR) mechanism is impacted by environmental factors during the lithographic process.

During exposure, a photo acid generator (PAG) is present, which releases an acid (H⁺) upon exposure to light. This acid initiates the deprotection of the protection group (PG) of a polymer chain, altering the solubility of the resist 15.

During PEB this reaction continues. The acid further catalyzes the removal of the PG during the baking process. The presence of airborne amines can neutralize the acid, inhibiting the deprotection reaction and affecting the critical dimension (CD) control.

Environmental conditions play an important role in the process. Controlling amine levels may allow for consistent lithographic performance.

Through its comprehensive capabilities for controlled environment processing and analysis, this tool 10 provides a valuable platform for evaluating photoresist chemical changes during lithographic processes, enabling optimization of process conditions and improved understanding of resist chemistry under various environmental conditions.

All FTIR spectroscopic data presented in the following examples were processed to ensure accuracy and repeatability. Raw transmittance spectra were converted to absorbance spectra, and a baseline correction was applied to remove noise and create a flat baseline. This process allowed for the clear resolution of characteristic absorption peaks, such as those for water (H₂O) and C—H bonds in ligands, with a high signal-to-noise ratio.

### Example 1: Investigation of Post-Exposure Delay Effects on Metal Oxide Resist Chemistry

Multiple MOR-[Ac] coated coupons with 25 nm film thickness were prepared and loaded into the system's sample garage 160 located in the intermediate chamber. Each coupon was individually processed through the exposure chamber 20 at an EUV dose of 35 mJ/cm². After exposure, the samples were subjected to different post-exposure delay (PED) conditions to study the impact of the ambient environment.

A first sample was immediately analyzed by FTIR in the intermediate chamber 40 under vacuum conditions to establish a baseline. Another sample (Sample 1) was stored in the controlled environment (CE) of the sample garage 160 under vacuum (~1×10⁻² mbar) for periods of up to four hours. A separate, identical sample (Sample 2) was removed from the tool and exposed to a noncontrolled cleanroom (CR) atmosphere with 45% relative humidity (RH) for the same time intervals before being reintroduced to the tool for FTIR analysis. For all measurements, the FTIR chamber was purged with N₂ to prevent atmospheric interference during analysis.

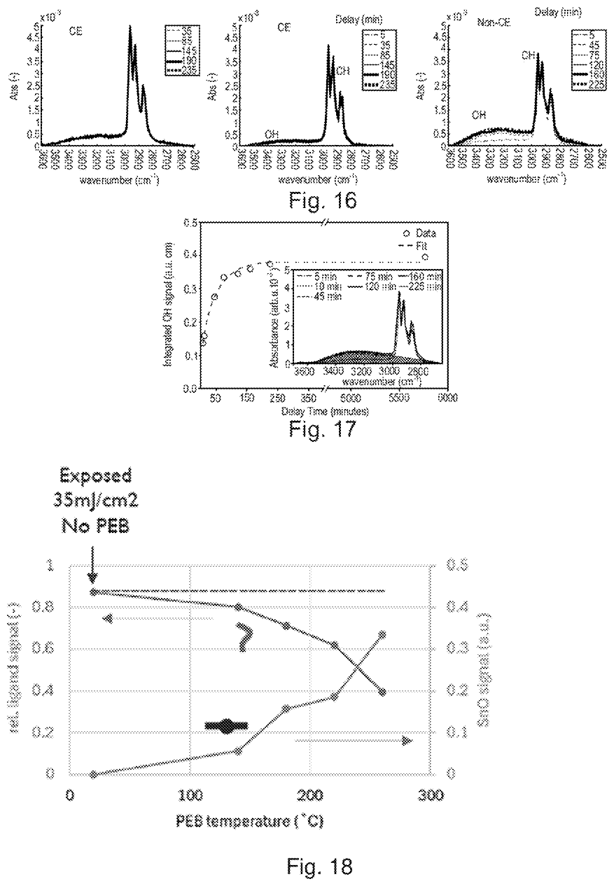

The results of this comparative study are clearly shown in FIG. 16. For the sample maintained in the controlled vacuum environment (CE, middle pane), the overlaid FTIR spectra at various delay times showed minimal changes. This demonstrated excellent control over the sample's chemical state. In stark contrast, the sample exposed to the non-controlled cleanroom air (Non-CE, right pane) showed a significant and time-dependent increase in the OH peak around 3400 cm⁻¹, indicating progressive moisture uptake.

The high sensitivity of the tool allowed for an even more detailed analysis of the resist's stability, as demonstrated in FIG. 16 (left and middle panes). A closer examination of the exposed sample held in the controlled environment revealed extremely subtle but consistent changes over time in the C—H ligand peaks. A control experiment on an unexposed sample showed no such changes, confirming that this minor instability was a real, exposure-induced phenomenon and showcasing the system's excellent sensitivity.

The moisture uptake from the non-controlled environment was quantified by integrating the OH signal over time, as plotted in FIG. 17. The graph shows a clear upward trend that begins to level off, indicating that the resist film was becoming saturated with water from the ambient air. The significance of this chemical change stems from the correlation between moisture uptake during PED and critical dimension (CD) variations. This confirms that the molecular-level changes measured by the tool have a direct impact on final lithographic performance.

After the delay-period characterization, all samples were transferred to the bake chamber 30 and subjected to a post-exposure bake (PEB). Post-bake FTIR analysis revealed that samples exposed to cleanroom air during the delay period showed different degrees of Sn—O—Sn condensation compared to those maintained in vacuum. This experiment successfully demonstrated the tool's ability to precisely measure and quantify how environmental exposure during post-exposure delay drives chemical changes that are directly linked to lithographic outcomes.

### Example 2: Step-by-Step Optimization of the Post-Exposure Bake Process

A series of experiments was conducted to demonstrate the tool's capability to systematically investigate and optimize the post-exposure bake (PEB) process by decoupling the effects of temperature, moisture, and atmospheric composition on the key chemical reactions in a metal oxide resist.

First, the tool was used to quantify the fundamental kinetics of the PEB step as a function of temperature. A MOR-[OH] sample was exposed to a uniform EUV dose of 35 mJ/cm². The sample was then subjected to a PEB in the thermal processing station 30 at various temperatures ranging from 140° C. to 260° C. under a controlled N₂/45% RH atmosphere. The results, plotted in FIG. 18, highlight the unique analytical power of the integrated system. The in-situ FTIR measurements allowed for the simultaneous tracking of two critical, opposing reactions: as the PEB temperature increased, the relative ligand signal clearly decreased, indicating thermally induced ligand cleavage. Concurrently, the SnO signal, corresponding to the formation of the Sn—O—Sn network, showed a distinct increase. This demonstrates the tool's ability to provide quantitative data on both ligand removal and network condensation, which is essential for optimizing the bake temperature to achieve the desired resist chemistry.

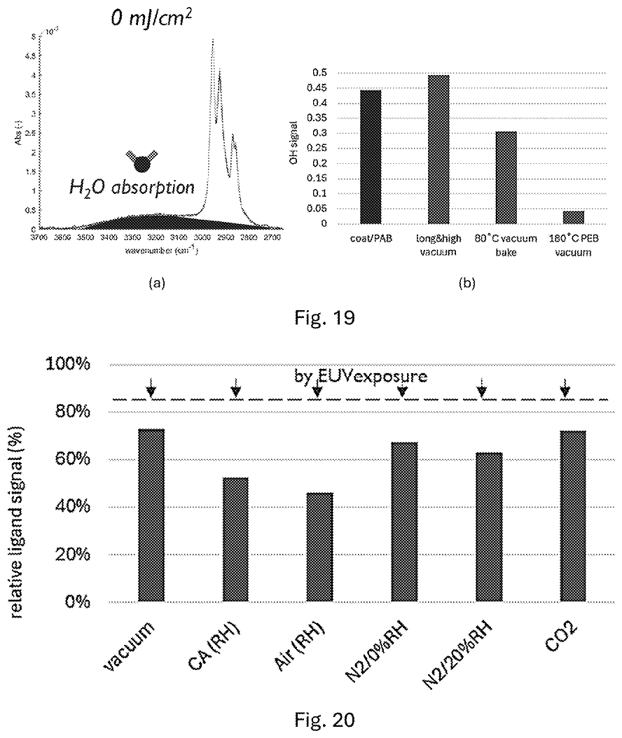

The tool was also used to track the stability and removal of moisture, a critical environmental factor, throughout the lithographic sequence. An initial FTIR measurement of an unexposed MOR-[OH] sample after coating and post-application bake (PAB), shown in FIG. 19a, revealed a significant H₂O absorption peak, establishing the baseline moisture content. FIG. 19b presents a bar chart summarizing the OH signal at subsequent processing stages. It shows that while vacuum steps can reduce moisture levels when performed at 80° C., higher-temperature steps on the order of a typical PEB are most effective at removing the majority of the moisture from the film. This confirms the tool's ability to monitor and verify the conditioning of the resist film at each stage.

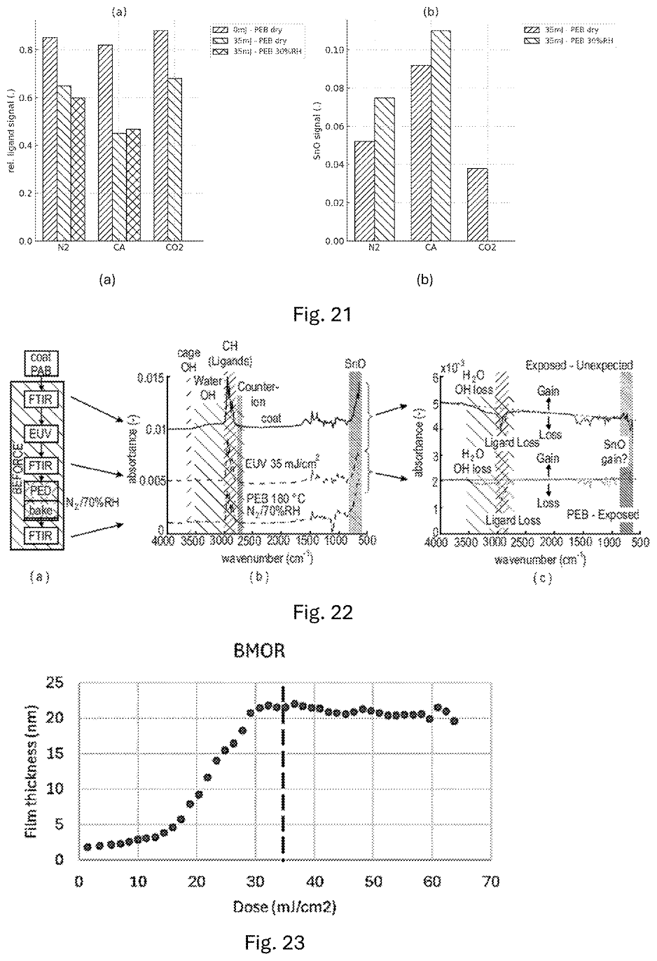

Building on this understanding of thermal and moisture effects, a comprehensive experiment was conducted to determine the impact of different atmospheric compositions during a fixed PEB. A series of identical MOR-[Ac] coupons was exposed to 35 mJ/cm² EUV and baked at 180° C. under various environments. The results, shown in the bar chart in FIG. 20, demonstrated that the atmospheric composition had a significant impact on ligand cleavage, with oxygen-containing environments (CA and Air) being the most effective. This conclusion was strongly reinforced by a dedicated study on the MOR-[Piv] resist, with results shown in FIG. 21a and 21b. As seen in FIG. 21a, the ligand loss was again most significant in the dry Clean Air (CA) environment, confirming that the presence of oxygen strongly enhances thermal ligand cleavage. Concurrently, FIG. 21b shows that the Sn—O condensation signal was also most pronounced in the CA atmosphere. Interestingly, the presence of humidity (30% RH) appeared to slightly facilitate the Sn—O condensation reaction, suggesting that while oxygen is key for ligand removal, water plays a role in the network formation. This detailed analysis, made possible by the tool's precise environmental control, allows for the fine-tuning of the PEB atmosphere to optimize both critical reactions simultaneously.

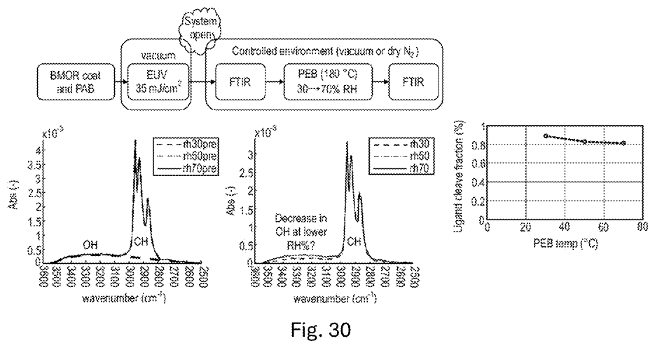

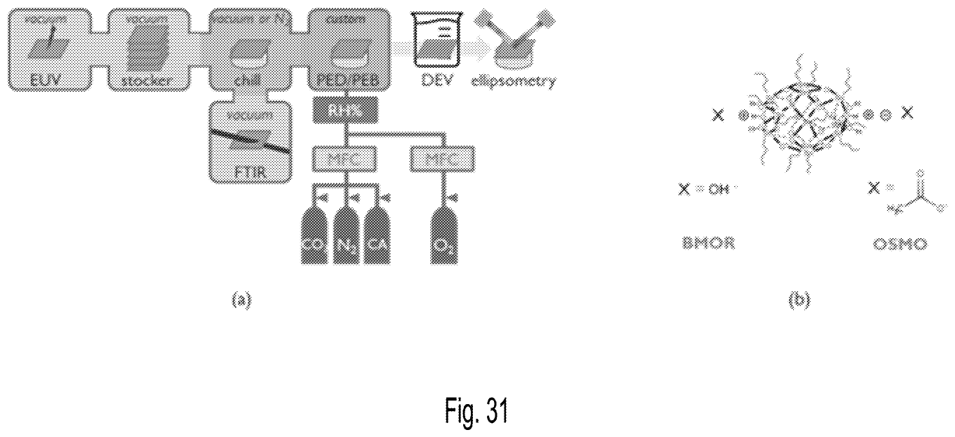

To further dissect the specific role of humidity during the PEB, another experiment was performed as detailed in FIG. 30. A BMOR sample was exposed to 35 mJ/cm² EUV radiation and then subjected to a PEB at a fixed temperature of 180° C., but with the relative humidity (RH) varied from 30% to 70% in a controlled N₂ atmosphere. The FTIR spectra taken before the bake confirmed the initial samples were identical. After the bake, the spectra suggested a potential trend where samples baked at lower RH had a slightly lower final OH signal, indicating less residual moisture. However, the graph of ligand cleave fraction versus the PEB humidity level showed that the extent of ligand removal was consistently high (around 80%) and virtually unaffected by the humidity level during the bake. This experiment, enabled by the tool's integrated humidity control, indicates that for this specific temperature, water vapor in the baking ambient does not significantly inhibit or enhance the primary thermal ligand cleavage reaction, although it may influence the final film hydration. Such studies may allow for defining robust process windows and identifying subtle environmental sensitivities.

### Example 3: Step-by-Step Chemical Analysis of a Full Lithographic Process

A detailed analysis of the chemical changes in a photoresist was performed at various stages of the lithographic process using the tool, as illustrated in FIGS. 22a, 22b, and 22c.

The experiment followed the process flow shown in FIG. 22a. A photoresist sample was prepared by coating and performing a post-application bake (PAB). The sample was then loaded into the tool, and an initial FTIR measurement was taken to establish a baseline. The sample was subsequently transferred to the exposure station and exposed to EUV radiation at a dose of 35 mJ/cm². Following exposure, a second FTIR measurement was performed. The sample then underwent a post-exposure delay (PED) before being transferred to the thermal processing station for a post-exposure bake (PEB) at 180° C. in a controlled nitrogen environment with 70% relative humidity (N₂/70% RH). A final FTIR measurement was conducted after the bake step.

The results are presented in FIG. 22b and 22c. FIG. 22b shows the FTIR spectra collected at three key stages: after coating (top line), after EUV exposure (middle line), and after the post-exposure bake (bottom line). The changes in the spectral regions corresponding to water (OH), ligands (CH), counter-ions, and Sn—O bonds clearly indicated that significant chemical transformations, such as ligand removal and Sn—O condensation, occurred at each step.

To better emphasize these changes, differential spectra were calculated, as shown in FIG. 22c. The spectrum calculated by subtracting the unexposed spectrum from the exposed spectrum (top line) revealed negative peaks for ligands and OH, confirming their loss during exposure. The differential spectrum comparing the post-bake state to the post-exposure state (bottom line) showed a further loss of ligands and OH, coupled with a distinct positive peak corresponding to the gain of Sn—O bonds. This experiment successfully demonstrated the tool's capability to track specific molecular transformations throughout a complete, environmentally controlled lithographic process.

### Example 4: Systematic Investigation of Dose and Temperature Effects

A series of experiments was conducted to demonstrate the tool's core capability to systematically decouple and quantify the chemical impacts of EUV dose and post-exposure bake (PEB) temperature on a model Metal Oxide Resist (BMOR).

### Part A: EUV Dose-Dependent Chemical Changes

A preliminary experiment was performed to determine the resist's dose-to-gel (D2G) threshold. As shown in FIG. 23, the remaining film thickness of the BMOR sample was measured after exposure to a range of EUV doses. The film thickness was observed to plateau around 20 nm at a dose of approximately 35 mJ/cm², which was identified as the D2G threshold and selected as the standard dose for subsequent thermal studies.

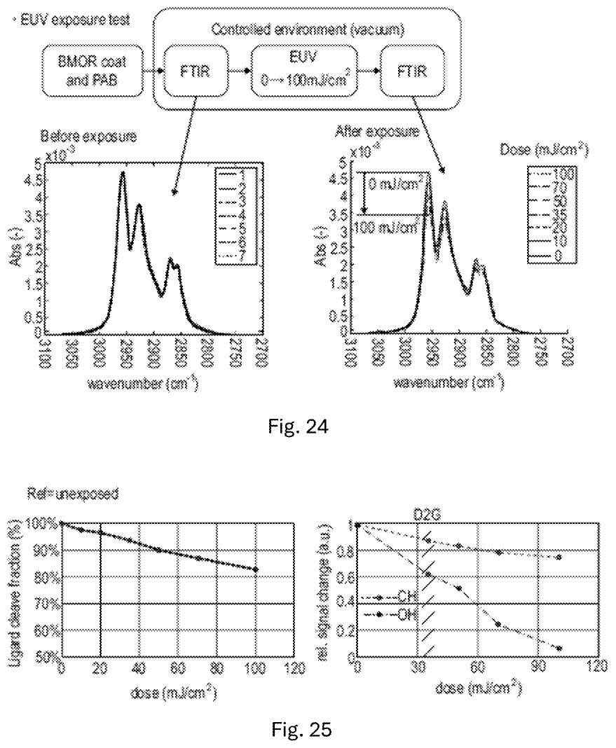

Next, the dose-dependent chemical changes were directly measured using the tool 10. A BMOR-coated sample was prepared, and a baseline FTIR measurement was taken. The sample was then exposed to a range of EUV doses from 0 to 100 mJ/cm² in the controlled vacuum environment of the exposure station 20. A final FTIR measurement was performed in the intermediate analysis station 40. The results, presented in FIG. 24, showed a clear, dose-dependent chemical response. As the EUV dose increased, the intensity of the C—H stretching peaks associated with the resist's ligands decreased, providing direct evidence of ligand removal. This relationship was quantified in FIG. 25 (left), which plots the ligand cleave fraction as a function of exposure dose, showing a clear trend of increased ligand removal with higher doses.

A more comprehensive view of the chemical kinetics during exposure is provided in FIG. 25 (right). This figure simultaneously tracks the relative signal change for both the organic ligands (CH) and the water content (OH) as a function of EUV dose. The top line confirms the gradual cleavage of ligands, consistent with the data in FIG. 25 (left), illustrating how the remaining fraction provides insights into exposure kinetics. More strikingly, the bottom line reveals a rapid and significant decrease in the OH signal, indicating that the EUV exposure process itself is highly effective at removing moisture from the resist film. The D2G threshold dose (around 35 mJ/cm², highlighted) corresponds to a point where nearly 40% of the initial moisture has been removed. Without being bound by theory, it is believed that at 0 mJ/cm², the Sn-cages are surrounded by numerous ligands and water molecules. As the dose increases to 35 mJ/cm² and then to 100 mJ/cm², both the number of ligands and, more dramatically, the number of water molecules decrease. This demonstrates the tool's powerful ability to monitor multiple, simultaneous chemical changes within the resist film as a direct consequence of the exposure step, distinguishing between the primary photoreaction (ligand cleavage) and secondary effects (moisture removal).

### Part B: Post-Exposure Bake (PEB) Temperature-Dependent Chemical Changes

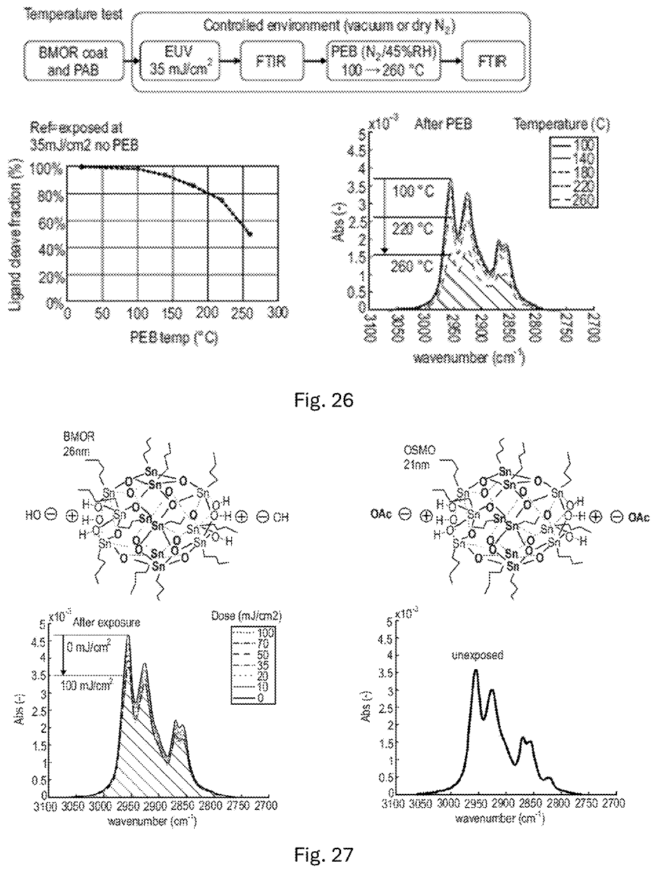

To isolate the effects of thermal processing, a BMOR sample was first exposed to a uniform EUV dose of 35 mJ/cm². The sample was then transferred to the thermal processing station 30 and subjected to a PEB in a controlled environment at temperatures ranging from 100° C. to 260° C. FTIR analysis was performed after each bake. The results, shown in FIG. 26, demonstrated a strong correlation between PEB temperature and further ligand removal. The intensity of the C—H stretching peaks continued to decrease significantly as the PEB temperature increased.

The data confirmed that both exposure dose and PEB temperature drive ligand cleavage, but their kinetics could be independently quantified. Furthermore, the tool allowed for the simultaneous tracking of other chemical changes, such as Sn—O condensation, providing a complete picture of the resist chemistry.

### Example 5: Comparative Analysis of Different MOR Formulations

To showcase the tool's utility for material screening and comparative studies, two different model metal oxide resists, BMOR and OSMO, were analyzed under identical processing conditions.

The objective was to directly compare the chemical response of BMOR (with hydroxide counter-ions) and OSMO (with acetate counter-ions) to both EUV radiation and post-exposure bake.

Samples of both BMOR and OSMO were prepared and loaded into the tool (10). Each sample was subjected to an identical process flow: an initial FTIR scan, followed by exposure to a range of EUV doses, and a subsequent FTIR scan. A separate set of exposed samples was then subjected to a PEB at various temperatures (100° C., 220° C., and 260° C.) followed by a final FTIR analysis.

The comparative response to EUV exposure is shown in FIG. 27. Both resists exhibited similar dose-dependent ligand removal, as evidenced by the decreasing intensity of the C—H peaks in their respective FTIR spectra. This indicated that the fundamental photo-cleavage mechanism was consistent between the two formulations.

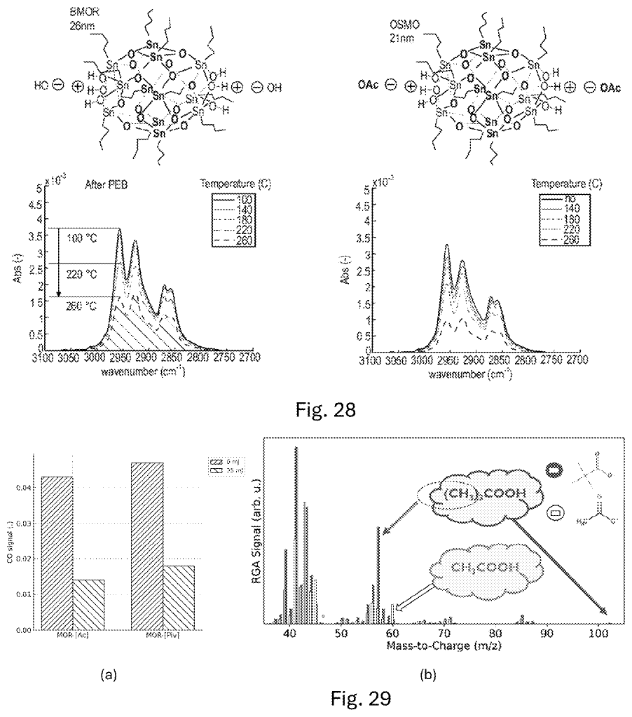

The comparative thermal behavior is shown in FIG. 28. Again, both resists displayed similar trends, with significant ligand removal occurring as the PEB temperature increased. The changes observed in the OSMO spectra were noted to be in line with those of BMOR, suggesting comparable thermal stability and ligand removal patterns.

This experiment demonstrated the tool's exceptional value for generating high-fidelity, directly comparable data on different material formulations. By ensuring that all processing and measurement conditions are identical and free from environmental variability, the tool enables researchers to confidently attribute observed differences in chemical behavior directly to the molecular structure of the resists themselves.

### Example 6: In-Situ Analysis of Counter-Ion Transformations During EUV Exposure

The tool 10 was utilized to investigate the transformation of counter-ions during EUV irradiation, a subtle but important chemical event. The study focused on the MOR-[Ac] and MOR-[Piv] model resists, which have distinct counter-ions.

As shown in FIG. 29a, FTIR measurements of the C—O stretching signal around 1550 cm⁻¹ were used to quantify the counter-ion presence. After exposure to an EUV dose of 35 mJ/cm², both materials exhibited a clear and similar decrease in the C—O signal, indicating a loss or transformation of the counter-ions.

To further investigate this, the integrated residual gas analyzer (RGA) in the exposure station 20 was used to perform outgas measurements during irradiation. The mass-to-charge spectrum, shown in FIG. 29b, revealed that while most outgassing peaks corresponded to butyl-related ligand fragments for both materials, specific masses showed distinct differences. The MOR-[Piv] sample exhibited a significantly higher peak at m/z=102, corresponding to pivalic acid, while the MOR-[Ac] sample showed a stronger signal at m/z=60, related to acetic acid. These combined FTIR and RGA findings strongly suggest that the counter-ions undergo protonation during EUV exposure, converting into their respective volatile acids. This experiment demonstrates the tool's unique capability to correlate changes within the film (via FTIR) with volatile byproducts (via RGA) in a single, controlled process sequence.

### Example 7: Dose Reduction Strategy for MOR by the Atmospheric Environment of the PEB

As noted above, metal oxide resists (MOR)—composed of relatively smaller and simpler molecular systems compared to conventional polymer-based photoresists—have emerged as promising candidates for extreme ultraviolet (EUV) lithography due to their high resolution, low line-edge roughness, and reduced EUV dose sensitivity. However, their chemical behavior post-EUV exposure is susceptible to variations in atmospheric conditions, potentially impacting lithographic performance and critical dimension (CD) control. On one hand, this can affect the stability of the CD-control, but on the other hand this offers opportunity to improve the process towards dose correction.

Through experimental work, using a tool similar to the tool 10 described above, it was determined that increasing oxygen levels during the post exposure bake (PEB) step resulted in an improvement in photo-speed. In particular, it was observed that increasing the oxygen concentration during PEB from 21% to 50% resulted in a ~30% improvement in photo-speed. These findings highlight the significance of PEB atmosphere composition—alongside temperature—as a critical parameter for optimizing EUV productivity in commercial MOR materials.

The tool 10, schematically shown in FIG. 31a, has EUV exposure capability as well as bake, and mimics in this way the EUV litho cluster for the post exposure process events. Specific to the tool 10 described herein is that the MOR material is continuously kept in a controlled environment that is sealed from the clean-room atmosphere. After EUV exposure, the MOR samples may be kept in an inert environment (e.g., vacuum or nitrogen). For PED and PEB processes, a well-defined environment can be chosen which can be well beyond the typical air-like atmosphere from the cleanroom. In example embodiments, dry gases N₂, CO₂, O₂ and fab clean air (CA, i.e. composed by 21% O₂, 78% N₂, 0.9% Ar, 0.04% CO₂) may be connected to the chamber with the ability of MFC control and mixing. In addition, the gases may be humidified at a specified percentage of relative humidity (% RH). Typical PEB temperatures for the investigated MOR materials are 180-220° C. In example embodiments, the PED and PEB times that the MOR is exposed to the environment are in the range of 60-120s.

The tool 10 described herein may use Fourier Transform Infrared (FTIR) spectroscopy for in situ monitoring of chemical changes in metal oxide resists (MOR) throughout various stages of the lithographic process, including sample introduction, EUV irradiation, and PED/PEB. Maintaining the MOR samples in an inert atmosphere during the measurements may allow for high signal-to-noise ratios in the acquired spectra, thereby facilitating precise analysis of chemical transformations during critical processing steps.

Following the PEB step-after which the MOR is anticipated to exhibit reduced environmental sensitivity-post-processing and evaluation can be conducted external to the tool 10. In example embodiments, MOR samples underwent wet development using a standard MOR developer, and the residual resist film thickness was subsequently measured via spectroscopic ellipsometry (KLA F5). To efficiently generate development contrast curves under diverse PED/PEB conditions, each MOR coupon sample was exposed at 12 discrete locations, enabling rapid assessment of environmental impacts on MOR photospeed. From the measured film thickness (FT) at the different doses, the dose-to-gel (D2G) was calculated by least square fitting of the data to following equation:

$$FTfit = FT max + \frac{( F T min - F T max )}{( 1 + {( \frac{d o s e}{D 2 G} )}^{c o n t r a s t} )}$$

In the equation, FTmax, FTmin, D2G, and contrast are the fitted variables.

This example study systematically investigated which environmental factors most significantly influence MOR photospeed and whether photospeed could be improved by increasing the concentration of atmospheric gases or humidity. Experiments included two model resists—BMOR and OSMO, which share a tin-cage core but differ in their counter-ions, as depicted in FIG. 31b—and a commercial MOR, designated as com-MOR in the subsequent results.

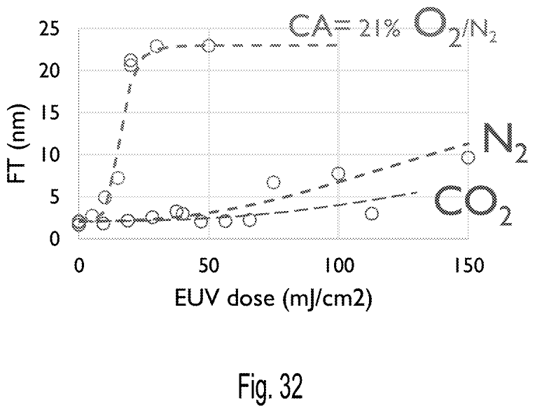

In an initial set of experiments, the individual effects of prevalent atmospheric constituents-namely N₂, CO₂, and O₂—in combination with nominal relative humidity, were evaluated using the BMOR model resist to determine their influence on photospeed. For the N₂ and CO₂ conditions, the chamber atmosphere consisted of each gas at 100% concentration. Due to safety constraints prohibiting the use of 100% O₂, clean air (CA), corresponding to 21% O₂ in N₂, was utilized to represent the oxygen environment. This was justified as the other air components were already addressed in the respective N₂ and CO₂ tests. The outcomes of these tests are presented in FIG. 32. Both pure N₂ and CO₂ atmospheres exhibited minimal sensitivity to condensation, as evidenced by low photospeed even at elevated exposure doses. In contrast, the CA environment demonstrated a markedly increased sensitivity to condensation, suggesting that oxygen plays a critical role in the condensation reaction.

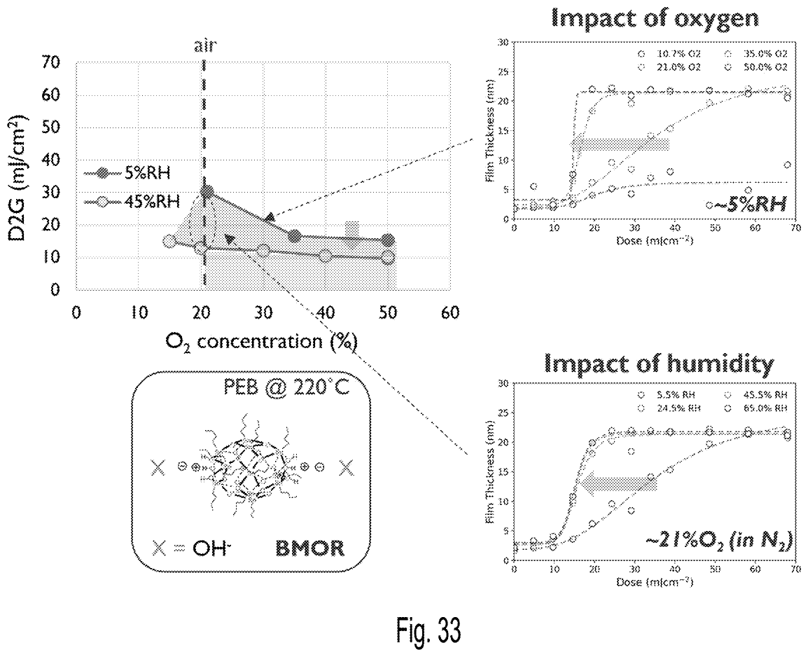

To systematically assess the influence of oxygen concentration and relative humidity on photospeed, a series of controlled experiments were performed employing BMOR and OSMO model MORs, as well as the commercial MOR formulation. The experimental conditions included either nominal relative humidity (~45% RH) or minimal humidity (~5% RH), thereby isolating the effects of atmospheric moisture in conjunction with varying oxygen levels. The D2G metric, indicative of the photospeed and calculated as dose required for 50% film thickness, was evaluated as a function of oxygen concentration during both PED and PEB, with identical atmospheric conditions maintained throughout these process steps. The resulting data is presented in FIGS. 33-35.

For BMOR (FIG. 33), elevating the oxygen concentration from atmospheric levels (21% O₂, representative of air) to ~50% O₂—the maximum permissible within the research tool—led to a pronounced reduction in D2G, signifying enhanced photospeed. Specifically, under low humidity (~5% RH), D2G decreased by approximately 50%, while under higher humidity (~45% RH), the reduction was around 20%. Relative humidity itself exerted a substantial effect on D2G; at air-like oxygen concentrations, the reduction approached 50%, whereas at elevated oxygen levels, the decrease remained near 20%. Notably, when oxygen concentrations fell below atmospheric levels, BMOR exhibited a negligible solubility switch, even at exposure doses up to ~100 mJ/cm², underscoring the necessity of sufficient oxygen for effective condensation reactions within this resist matrix.

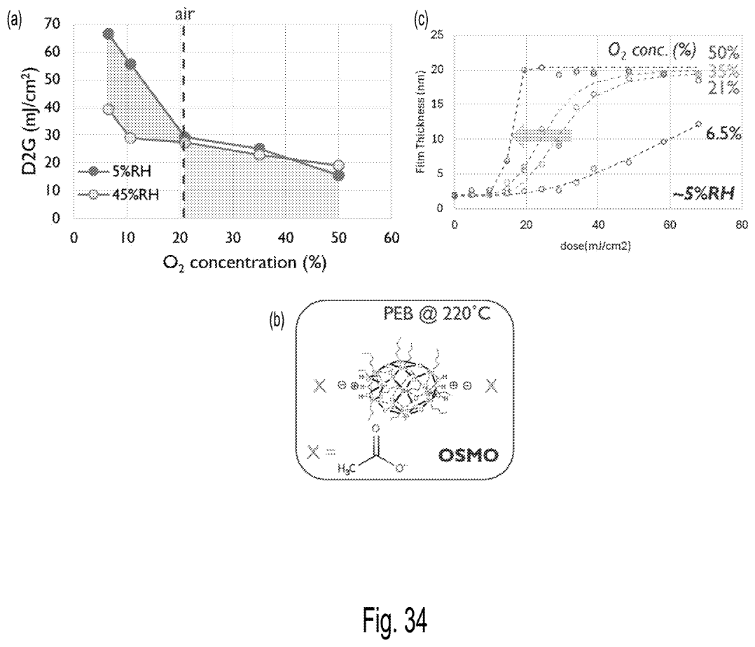

In the case of OSMO (FIGS. 34a, 34b, 34c), which differs from BMOR primarily in its counter-ion composition, an overall reduction in D2G was likewise observed as oxygen concentration increased, with a decrease nearing 30% from air-like to 50% O₂. Unlike BMOR, the impact of relative humidity on D2G was minimal at higher oxygen concentrations; however, at reduced oxygen levels, increased humidity provided a measurable benefit. Importantly, OSMO maintained its solubility switching capability even at lower oxygen concentrations, in contrast to BMOR.

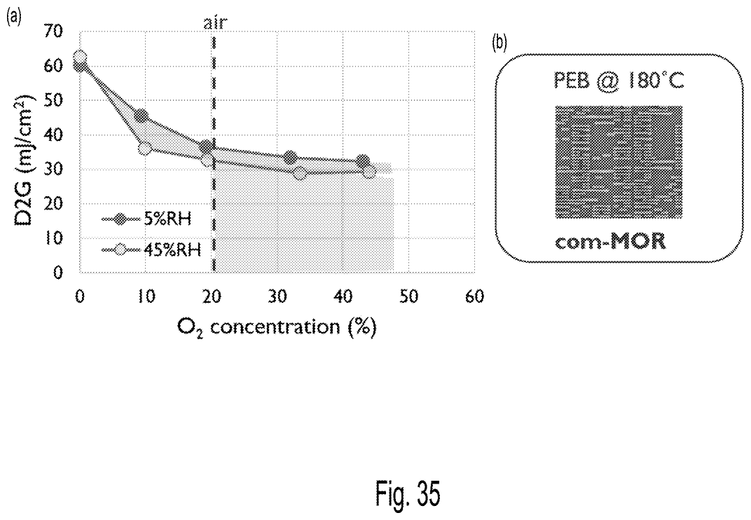

For the commercial MOR (FIGS. 35a, 35b), the D2G trends as a function of oxygen concentration closely mirrored those observed with the model resists, albeit with somewhat attenuated magnitude. The data nonetheless supports a beneficial effect of elevated oxygen concentration on photospeed. Additionally, relative humidity contributed an approximate 10% reduction in D2G. It is noteworthy that this commercial resist demonstrated condensation even in the absence of oxygen, though the corresponding D2G was nearly double that observed under nominal atmospheric conditions.

Further, experiments were conducted with identical environmental conditions maintained during both the PED and PEB processes to distinguish the individual contributions of PED and PEB environments to the overall dose response. It should be noted that, within example embodiments of the tool 10, samples spend most of the PED duration in vacuum storage (<10⁻² mbar, stocker), and prior investigations have established that no significant chemical transformations occur during this interval. Consequently, for the example embodiments described herein in relation to the tool 10, PED time predominantly refers to the period when the sample is placed in the PEB chamber before being transferred onto the hotplate. When PED and PEB are performed under the same atmospheric conditions, in example embodiments, this PED interval typically lasts approximately one minute.

To assess the separate effects of PED and PEB atmospheres, preliminary experiments were conducted in which the environment was altered: an initial PED phase was carried out in the PEB chamber (approximately 120 seconds), followed by a switch to a different atmospheric condition upon sample contact with the hotplate. It should be acknowledged that environmental transitions within the same chamber may introduce a period of uncertainty regarding the precise PED and PEB durations, thereby affecting the accuracy of the reported D2G values.

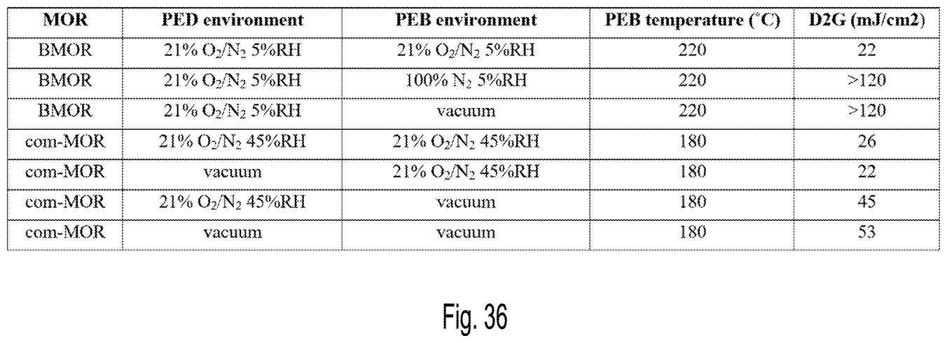

Under these conditions, development contrast curve tests were performed using both OSMO and the commercial MOR, with distinct environmental settings applied during PED and PEB. The experimental parameters and corresponding D2G results are summarized in the table of FIG. 36.

In the initial experiment, OSMO material underwent a PED in a stable environment consisting of 21% O₂/N₂ and 5% RH, followed by PEB under varying environmental conditions. The table of FIG. 36 shows that D2G was notably low when PEB was performed at an air-like oxygen concentration. Conversely, when PEB was conducted under oxygen-free or vacuum conditions, the solubility switch was not observed within the applied EUV dose range up to 120 mJ/cm². These findings indicate that the environmental conditions during PEB predominantly govern the condensation process.

In a subsequent experiment, com-MOR material was employed, wherein the PED and PEB environments were alternated between 21% O₂/N₂ at 45% relative humidity and vacuum in various combinations. Consistent with prior results, PED/PEB conducted entirely in 21% O₂/N₂ at 45% RH yielded a low D2G of approximately 26 mJ/cm². Alternatively, PED/PEB performed in vacuum/vacuum resulted in a higher D2G of about 53 mJ/cm², similar to N₂/N₂ conditions previously described (note that both D2G values are slightly lower due to the extended PEB duration of 2 minutes, as will be discussed below). When the PED/PEB environments were switched from 21% O₂/N₂ at 45% RH to vacuum and vice versa, the resulting D2G was primarily determined by the PEB environment. Collectively, these experiments suggest that the PEB environment exerts a dominant influence on the condensation reaction.

Optimization of PEB parameters, including temperature and duration, is critical for maximizing lithographic process efficiency, with dose sensitivity serving as a principal metric for productivity. In addition to these well-established factors, the results above have demonstrated that the PEB environment—particularly its oxygen concentration—has a significant impact on dose sensitivity. This finding motivates a comprehensive assessment of the interrelationships among PEB temperature, PEB duration, and environmental conditions.

To evaluate these variables, a series of experiments were conducted using the com-MOR material. The PED and PEB environments were set to nominal oxygen concentrations of 0%, 20%, and 45%, at a low relative humidity of approximately 5%. Further on, PEB temperature was varied from 160° C. to 200° C. The results, illustrated in FIG. 37a, corroborate established trends in MOR processing: at a nominal oxygen concentration of 20% (comparable to ambient air), D2G decreased by approximately 60% as PEB temperature increased from 160° C. to 200° C. When the oxygen concentration was elevated to 45%, the reduction in D2G was even more pronounced, at approximately 75%. In contrast, PEB performed in an oxygen-free environment elicited negligible change in D2G across this temperature range. This data suggests a pronounced, non-linear interaction between oxygen concentration and PEB temperature on dose sensitivity.

This investigation demonstrates that the atmospheric environment during PED and PEB processes plays a critical role in determining the dose sensitivity of MOR materials, as assessed using the BEFORCE platform. Development contrast curve analyses on both model and commercial MORs reveal that while N₂ and CO₂ components from air exert minimal influence on the condensation reaction rate, O₂ and humidity substantially modify this rate. Notably, increasing oxygen concentration during PED and PEB markedly enhances dose sensitivity. Humidity generally improves dose sensitivity as well, though the extent of this benefit appears to depend on the specific resist chemistry.

Furthermore, it was observed that the environmental conditions during PEB have a dominant effect compared to those during PED. The observed reduction in dose due to the PEB environment is non-linear with respect to thermal effects, indicating that the PEB environment can be co-optimized with PEB temperature and duration to achieve improved lithographic process efficiency. These findings underscore the importance of environmental control during PEB for optimizing MOR performance and invite further investigation into the interplay between environmental and thermal factors in advanced lithography.

### I. Systems for EUV Processing Improvements by Atmospheric Environment

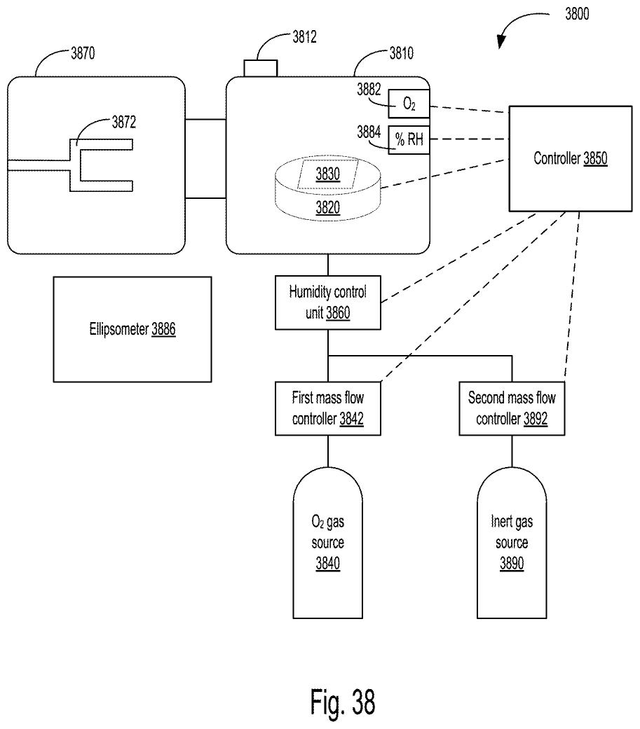

Given the importance of oxygen during PEB for MOR processing, the present disclosure provides for a system for controlling oxygen levels during thermal processing of MORs. FIG. 38 illustrates a system 3800 that may be similar to or identical to portions of the tool 10.

The system 3800 includes a thermal processing chamber 3810. The thermal processing chamber 3810 may be enclosed such that the environment within the chamber is closed system with an isolated environment. The thermal processing chamber 3810 may be similar or identical to the thermal processing station 30 described in relation to the tool 10.

The system 3800 may further include a hot plate 3820 disposed within the thermal processing chamber 3810. The hot plate 3820 may be similar or identical to the hot plate 32 described in relation to the tool 10. That is, the hot plate 3820 may be a heating apparatus for raising the temperature of a photoresist sample within a controlled range, typically from room temperature up to an upper setpoint. Examples include conduction-based plates with embedded heaters, or contactless thermal systems with precisely regulated heat transfer surfaces. The hot plate 3820 may be configured to support a MOR photoresist sample 3830.

The system 3800 may further include an O₂ gas source 3840 coupled to the thermal processing chamber 3810 by way of a first mass flow controller 3842. The first mass flow controller 3842 may be configured to precisely regulate the flow rate of oxygen gas into the thermal processing chamber.

Further, the system 3800 may include a controller 3850 having at least one processor and a memory storing program instructions. The at least one processor may execute the program instructions so as to carry out operations. The operations may include causing the hot plate 3820 to heat the MOR photoresist sample 3830 at a predetermined temperature for a predetermined period of time. For example, the controller 3850 may be communicatively connected to the hot plate 3820, such that it can control a setpoint and timer for the hot plate 3820. In example embodiments, the predetermined temperature is within a range of 50° C.-350° C., and the predetermined period of time is within a range of 60 seconds to 240 seconds. The predetermined temperature and the predetermined period of time may be selected (e.g., by the controller) based on the specific MOR material chemistry.

The operations carried out by the controller 3850 may further include adjusting the first mass flow controller 3842 to maintain a predetermined atmospheric condition in the thermal processing chamber 3810. In example embodiments, the predetermined atmospheric condition includes an O₂ concentration within the range of 0% to 50%, for example in the range of 22% to 50% such that the oxygen content is greater than it would be in normal atmospheric air. The specific O₂ concentration may be determined (e.g., by the controller) based on the specific MOR material chemistry in conjunction with other processing parameters such as the predetermined temperature and the predetermined period of time.

In some example embodiments, the system 3800 may further include a humidity control unit 3860 coupled to the thermal processing chamber 3810. The humidity control unit 3860 may be identical or similar to the humidity control unit 224 described in relation to the tool 10. That is, the humidity control unit 3860 may be a device that adjusts and controls the level of water vapor present in the thermal processing chamber's atmosphere. An example includes a bubbler that passes a carrier gas through water to achieve a defined relative humidity (RH), thereby allowing processes to be carried out under controlled moisture conditions. The humidity control unit 3860 may be communicatively coupled to the controller 3850. In example embodiments, the operations of the controller 3850 may further include causing the humidity control unit 3860 to provide a predetermined relative humidity in the thermal processing chamber 3810. The predetermined relative humidity may be selected (e.g., by the controller 3850) based on the specific MOR material of the MOR photoresist sample 3830 and the other processing conditions (e.g., the oxygen concentration).

The system 3800 may further include an inert gas source 3890 coupled to the thermal processing chamber 3810 by way of a second mass flow controller 3892. In example embodiments, the operations of the controller 3850 may further include adjusting the second mass flow controller 3892 to maintain the predetermined atmospheric condition in the thermal processing chamber 3810. The predetermined atmospheric condition may include an N₂ or Ar concentration within a range of 50% to 78%. For example, the predetermined atmospheric condition may include an O₂ concentration within the range of 0% to 50%, for example 22% to 50%, and the remainder may be N₂, Ar, or a combination thereof. Other types of inert gases as well as reactive gases are contemplated and possible as well.

In some example embodiments, the system 3800 may further include a valve 3812 configured to maintain a predetermined pressure within the thermal processing chamber 3810. For example, the first mass flow controller 3842 and the second mass flow controller 3892 may collectively provide a slight overpressure of the mixture of oxygen gas and inert gas in the thermal processing chamber 3810. The valve 3812 may be an overpressure relief valve or similar, configured to maintain a specific pressure within the thermal processing chamber 3810.

Further, in example embodiments, the system 3800 may include an intermediate chamber 3870. The intermediate chamber 3870 may be similar or identical to the intermediate analysis station 40 described in relation to the tool 10. The intermediate chamber 3870 may have a neutral environment. For example, the intermediate chamber 3870 may be connected to an inert gas source, such as the inert gas source 3890, so to provide a neutral environment within the intermediate chamber 3870. In example embodiments, the intermediate chamber 3870 may be filled with N₂ or Ar. The intermediate chamber 3870 may be thermally and/or environmentally isolated from the thermal processing chamber 3810. For example, in between the thermal processing chamber 3810 and the intermediate chamber 3870, there may be environmental isolation means similar or identical to those described in relation to the tool 10. For example, the system 3800 may include structures, features, or components designed to preserve distinct atmospheric or vacuum conditions in separate subsystems (i.e., for the thermal processing chamber 3810 and the intermediate chamber 3870) preventing cross-contamination or pressure equalization among them. Examples include valves, gate mechanisms, seals, or isolation chambers arranged to allow sample transfer without compromising the environment in each station.

In example embodiments, the system 3800 may also include a sample transfer system 3872 configured to transfer the MOR photoresist sample 3830 between the intermediate chamber 3870 and the thermal processing chamber 3810. The sample transfer system 3872 may be similar or identical to the sample transfer system 80 described in relation to the tool 10. That is, the sample transfer system 80 may be a subsystem, including but not limited to robotic arms or manual handlers, configured to move a photoresist sample between stations without exposing that sample, or the stations (i.e., the thermal processing chamber 3810 and the intermediate chamber 3890), to undesired environmental changes. Examples include motorized transfer arms coordinated via a central control or manually operated stage-transfer devices, each capable of sealing off or isolating station environments during transport. In example embodiments, the sample transfer system 3872 may be controlled by the controller 3850.

Further, in example embodiments, the system 3800 may include one or more sensors to measure the present atmospheric condition within the thermal processing chamber 3810 and/or the intermediate chamber 3870. By way of example, the system 3800 may include an O₂ sensor 3882 configured to measure the O₂ concentration within the thermal processing chamber 3810. Similarly, the system 3800 may include a humidity sensor 3884 configured to measure a relative humidity within the thermal processing chamber 3810. The O₂ sensor 3882 and/or the humidity sensor 3884 may be communicatively coupled to the controller 3850 so as to collect and store data related to the sensor measurements. The measurements may also be used as feedback for controlling the first mass flow controller 3842 and the second mass flow controller 3892.

Even further, in example embodiments, the system 3800 may include measurement devices for measuring various properties of the MOR photoresist sample 3830 either in situ during thermal processing, or before/after thermal processing. For example, the system 3800 may include an ellipsometer 3886 configured to measure a thickness of the MOR photoresist sample.

### II. Methods for EUV Processing Improvements by Atmospheric Environment

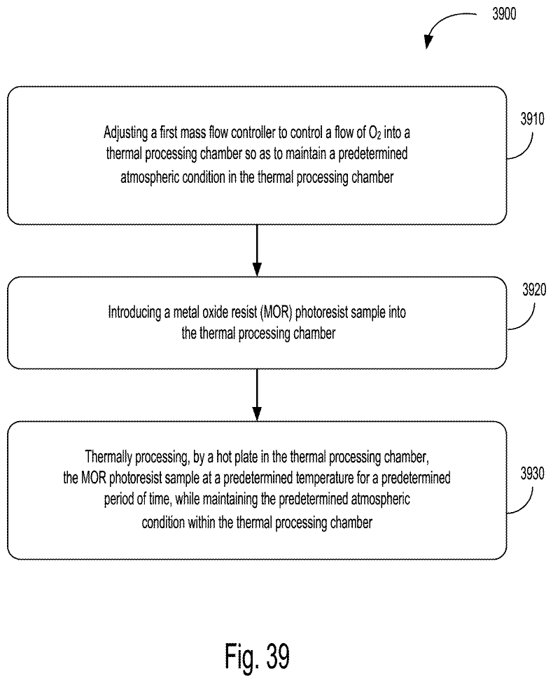

FIG. 39 illustrates a method 3900, according to example embodiments. In an example embodiment, method 3900 may be described in terms of steps or blocks. It will be understood that the method 3900 may include fewer or more steps or blocks than those expressly illustrated or otherwise disclosed herein. Furthermore, respective steps or blocks of method 3900 may be performed in any order and each step or block may be performed one or more times. In some embodiments, some or all of the blocks or steps of method 3900 may be carried out using a system similar, or identical, to the system 3800.

The method 3900 may include a block 3910 of adjusting a first mass flow controller (e.g., the first mass flow controller 3842) to control a flow of O₂ into a thermal processing chamber (e.g., the thermal processing chamber 3810) so as to maintain a predetermined atmospheric condition in the thermal processing chamber. In example embodiments, the predetermined atmospheric condition includes an O₂ concentration of 0% to 50%, for example 22% to 50%. Therefore in example embodiments, the chamber may have an elevated concentration of O₂, beyond the standard concentration in atmospheric air (~21%).

Further, in example embodiments, the method 3900 may include adjusting a second mass flow controller (e.g., the second mass flow controller 3892) to control a flow of an inert gas into the thermal processing chamber so as to maintain the predetermined atmospheric condition in the thermal processing chamber. The predetermined atmospheric condition may include N₂ or Ar at a concentration within a range of 50% to 78%, such that the remaining fraction of the thermal processing chamber is an inert gas.

In some example embodiments, the predetermined atmospheric condition may also include a predetermined relative humidity, such that the method 3900 further includes providing, by a humidity control unit (e.g., the humidity control unit 3860), the predetermined relative humidity in the thermal processing chamber.

The method 3900 may further include a block 3920 of introducing a metal oxide resist (MOR) photoresist sample (e.g., the MOR photoresist sample 3830) into the thermal processing chamber.

Further, the method 3900 may include a block 3920 of thermally processing, by a hot plate (e.g., the hot plate 3820) in the thermal processing chamber, the MOR photoresist sample at a predetermined temperature for a predetermined period of time, while maintaining the predetermined atmospheric condition within the thermal processing chamber. In example embodiments, the predetermined temperature may be within a range of 50° C.-350° C. and the predetermined period of time may be within a range of 60 seconds to 240 seconds.

In some example embodiments, before, during, or after thermally processing, the method 3900 may further include taking various measurements of the conditions in the thermal processing chamber and/or taking measurements related to the MOR photoresist sample. For example, the method 3900 may include measuring, by an O₂ sensor (e.g., the O₂ sensor 3882), the O₂ concentration within the thermal processing chamber. Alternatively, or in addition to, the method 3900 may include measuring, by a humidity sensor (e.g., the humidity sensor 3884), a relative humidity within the thermal processing chamber. Even further, the method 3900 may include measuring, by an ellipsometer (e.g., the ellipsometer 3886), a thickness of the MOR photoresist sample.

Further, in example embodiments, the method may further include receiving, in an intermediate chamber (e.g., the intermediate chamber 3870), the MOR photoresist sample. The intermediate chamber may have a neutral environment and may be thermally isolated from the thermal processing chamber. The sample may remain within the intermediate chamber for a predetermined amount of time. In example embodiments, the block 3920 of introducing the MOR photoresist sample into the thermal processing chamber may include transferring, by a sample transfer system (e.g., the sample transfer system 3872), the MOR photoresist sample from the intermediate chamber to the thermal processing chamber. The sample may also be transferred back to the intermediate chamber after thermal processing. For example, subsequent to thermally processing the MOR photoresist sample, the method 3900 may include transferring, by the sample transfer system, the MOR photoresist sample from the thermal processing chamber to the intermediate chamber.

### LIST OF REFERENCE NUMBERS

10—Tool
15—Photoresist samples
20—Radiation exposure station
22—Radiation source
30—Thermal processing station
32—Hot plate
34—Sensors
40—Intermediate analysis station
42—System configured for analyzing photoresist samples/Fourier Transform Infrared (FTIR) spectrometer
60—Environmental isolation means
70—Atmosphere control system
80—Sample transfer system
90—Resist coat station
100—Developer station
110—Sample tilting mechanism/Goniometer
150—Temperature-controlled stage
160—Sample storage unit (e.g., garage or stocker)
170—Residual gas analyzer (RGA)
224—Humidity control unit
300—Controller
320—System
3800—System
3810—Thermal processing chamber
3812—Valve
3820—Hot plate
3830—MOR photoresist sample
3840—O₂ gas source
3942—First mass flow controller
3850—Controller
3860—Humidity control unit
3870—Intermediate chamber
3872—Sample transfer system
3882—O₂ sensor
3884—Humidity sensor
3886—Ellipsometer
3890—Inert gas source
3892—Second mass flow controller
3900—Method

It is to be understood that although example embodiments, specific constructions and configurations, as well as materials, have been discussed herein for devices according to the present disclosure, various changes or modifications in form and detail may be made without departing from the scope of this disclosure. For example, any formulas given above are merely representative of procedures that may be used. Functionality may be added or deleted from the block diagrams and operations may be interchanged among functional blocks. Steps may be added or deleted to methods described within the scope of the present disclosure.

Further, while some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A tool for evaluating photoresist chemical changes during lithographic processes, comprising:
a radiation exposure station for exposing photoresist samples to radiation;
a thermal processing station for thermally processing photoresist samples;
an intermediate analysis station separate from the radiation exposure station and the thermal processing station, the intermediate analysis station comprising a system configured for analyzing photoresist samples;
environmental isolation means between the stations enabling independent environments in each station during operation;
an atmosphere control system configured to establish different atmospheric conditions in each station; and
a sample transfer system for transferring photoresist samples between the stations while maintaining environmental isolation.

2. The tool of claim 1, wherein the system configured for analyzing photoresist samples in the intermediate analysis station comprises a Fourier Transform Infrared (FTIR) spectrometer.

3. The tool of claim 2, wherein the FTIR spectrometer is configured for transmission measurements through a photoresist sample.

4. The tool of claim 3, further comprising a sample tilting mechanism for tilting the photoresist sample to increase an optical path length for transmission measurements.

5. The tool according to claim 1, wherein the intermediate analysis station comprises a temperature-controlled stage.

6. The tool according to claim 1, further comprising a sample storage unit, connected to the sample transfer system for holding one or more photoresist samples under a controlled environment for defined periods.

7. The tool according to claim 1, wherein the radiation exposure station further comprises a residual gas analyzer (RGA) for monitoring outgassing from the photoresist samples during exposure.

8. The tool according to claim 1, wherein the atmosphere control system is configured to independently provide in any of the stations, atmospheres selected from the group consisting of high vacuum, low vacuum, clean air (CA), carbon dioxide (CO₂), oxygen (O₂), nitrogen (N₂), argon (Ar), or mixtures thereof.

9. The tool according to claim 1, wherein the atmosphere control system further comprises a humidity control unit for controlling relative humidity (RH) within one or more stations.

10. The tool according to claim 1, wherein the atmosphere control system is further configured to dose controlled amounts of airborne molecular contaminants (AMCs).

11. A system comprising:
a thermal processing chamber;
a hot plate disposed within the thermal processing chamber, wherein the hot plate is configured to support a metal oxide resist (MOR) photoresist sample;
an O₂ gas source coupled to the thermal processing chamber by way of a first mass flow controller; and
a controller having at least one processor and a memory storing program instructions, wherein the at least one processor executes the program instructions so as to carry out operations, the operations comprising:
causing the hot plate to heat the MOR photoresist sample at a predetermined temperature for a predetermined period of time, wherein the predetermined temperature is within a range of 50° C.-350° C., and wherein the predetermined period of time is within a range of 60 seconds to 240 seconds; and
adjusting the first mass flow controller to maintain a predetermined atmospheric condition in the thermal processing chamber, wherein the predetermined atmospheric condition comprises an O₂ concentration within a range of 22% to 50%.

12. The system of claim 11, further comprising:
a humidity control unit coupled to the thermal processing chamber, wherein the operations further comprise causing the humidity control unit to provide a predetermined relative humidity in the thermal processing chamber.

13. The system of claim 11, further comprising:
an intermediate chamber with a neutral environment, wherein the intermediate chamber is configured to receive the MOR photoresist sample, and wherein the intermediate chamber is thermally isolated from the thermal processing chamber; and
a sample transfer system configured to transfer the MOR photoresist sample between the intermediate chamber and the thermal processing chamber.

14. The system of claim 11, further comprising:
an O₂ sensor configured to measure the O₂ concentration within the thermal processing chamber;
a humidity sensor configured to measure a relative humidity within the thermal processing chamber; or
an ellipsometer configured to measure a thickness of the MOR photoresist sample.

15. The system of claim 11, further comprising:
an inert gas source coupled to the thermal processing chamber by way of a second mass flow controller, wherein the operations further comprise adjusting the second mass flow controller to maintain the predetermined atmospheric condition in the thermal processing chamber, wherein the predetermined atmospheric condition comprises an N₂ or Ar concentration within a range of 50% to 78%; and
a valve configured to maintain a predetermined pressure within the thermal processing chamber.

16. A method comprising:
adjusting a first mass flow controller to control a flow of O2 into a thermal processing chamber so as to maintain a predetermined atmospheric condition in the thermal processing chamber, wherein the predetermined atmospheric condition comprises an O2 concentration of 22% to 50%;
introducing a metal oxide resist (MOR) photoresist sample into the thermal processing chamber; and
thermally processing, by a hot plate in the thermal processing chamber, the MOR photoresist sample at a predetermined temperature for a predetermined period of time, while maintaining the predetermined atmospheric condition within the thermal processing chamber, wherein the predetermined temperature is within a range of 50° C.-350° C., and wherein the predetermined period of time is within a range of 60 seconds to 240 seconds.

17. The method of claim 16, wherein the predetermined atmospheric condition further comprises a predetermined relative humidity, and wherein the method further comprises providing, by a humidity control unit, the predetermined relative humidity in the thermal processing chamber.

18. The method of claim 16, further comprising:
measuring, by an O₂ sensor, the O₂ concentration within the thermal processing chamber;
measuring, by a humidity sensor, a relative humidity within the thermal processing chamber; or
measuring, by an ellipsometer, a thickness of the MOR photoresist sample.

19. The method of claim 16, further comprising adjusting a second mass flow controller to control a flow of an inert gas into the thermal processing chamber so as to maintain the predetermined atmospheric condition in the thermal processing chamber, wherein the predetermined atmospheric condition comprises an N₂ or Ar concentration within a range of 50% to 78%.

20. The method of claim 16 further comprising:
receiving, in an intermediate chamber, the MOR photoresist sample, wherein the intermediate chamber has a neutral environment and is thermally isolated from the thermal processing chamber, wherein introducing the MOR photoresist sample into the thermal processing chamber comprises transferring, by a sample transfer system, the MOR photoresist sample from the intermediate chamber to the thermal processing chamber; and
subsequent to thermally processing the MOR photoresist sample, transferring, by the sample transfer system, the MOR photoresist sample from the thermal processing chamber to the intermediate chamber.
